(19) United States
(12) Patent Application Publication
(10) Pub. No.: US 2009/0174435 A1
(43) Pub. Date: Jul. 9, 2009

(54) Monolithically-Integrated Graphene-Nano-Ribbon (GNR) Devices, Interconnects and Circuits

(75) Inventors: Mircea R. Stan, Charlottesville, VA (US); Avik Ghosh, Charlottesville, VA (US)

Correspondence Address: Oppedahl Patent Law Firm LLC - SRC, P.O. Box 4850, Frisco, CO, 80443-4850, US

(73) Assignee: University of Virginia, Charlottesville, VA (US)

(21) Appl. No.: 12/243,165

(22) Filed: Oct. 1, 2008

Related U.S. Application Data
(60) Provisional application No. 60/997,056, filed on Oct. 1, 2007.

(51) Int. Cl. H03K 19/094; H01L 29/12; H03K 19/20

(52) U.S. Cl. 326/112; 257/14; 326/104; 257/E29.068; 977/755; 977/938; 977/940

(57) ABSTRACT

The invention discloses new and advantageous uses for carbon/graphene nanoribbons (GNRs), which includes, but is not limited to, electronic components for integrated circuits such as NOT gates, OR gates, AND gates, nano-capacitors, and other transistors. More specifically, the manipulation of the shapes, sizes, patterns, and edges, including doping profiles, of GNRs to optimize their use in various electronic devices is disclosed.

### CROSS-REFERENCE TO RELATED APPLICATIONS

This application claims priority from U.S. application No. 60/997,056, filed Oct. 1, 2007, which application is incorporated herein by references for all purposes.

### BACKGROUND

1. Background Discussion
NOTE: Some of the references referred in this subsection, using the reference number contained in the square brackets [ ], are listed to in the next subsection.

The semiconductor industry is facing very difficult challenges moving forward, as the scaling down of critical dimensions in standard bulk CMOS technologies is harder to achieve due to technical, technological, and economic constraints. Furthermore, even if scaling continues (probably at a slower pace), the resulting devices are likely to exhibit poor characteristics such as slow carrier mobility (slow performance), large off currents (leakage), large process variations, poor reliability, etc. There are several directions that promise to solve, or at least ease, some of the problems associated with scaling. Some of these directions use conventional top-down fabrication techniques (e.g., lithography), but try to obtain device structures that are intrinsically more scalable, such as the dual- and tri-gate devices (e.g., FinFET) investigated at Intel, UC Berkeley, etc., Other directions use novel bottom-up fabrication (i.e., self-assembly), such as Carbon Nano-Tubes (CNT) and molecular electronics, to overcome the limitations of lithography. Recently, there has been much excitement (and industry support) in the research community about the promise of CNTs. CNTs exhibit excellent intrinsic performance, high gain, high carrier mobility, high reliability, and, in general, are intrinsically an almost ideal device.

However, CNTs have several possible fatal flaws, in the fact that there is no clear strategy for arranging multiple such tubes on a substrate, and there is also no clear strategy for controlling the chirality of such CNTs. Most demonstrations until now have consisted of crude circuits obtained by manually selecting and arranging CNTs one by one, which is clearly unacceptable for any practical applications. The few experiments that used in-situ growth of CNTs (see Background references [5] and [51]) have still not shown applicability to general circuit design. On the other hand, the semiconductor industry has invested significantly in planar fabrication techniques, and solutions compatible with current practice are clearly preferable.

2. List of Related Art

The following is a listed of related art that is referred to in and/or forms some of the basis of other sections of this specification. All of these listed references are therefore incorporated by reference in their entirety for all purposes.
[1] J. Appenzeller, J. Knoch, V. Derycke, R. Martel, S. Wind, and P. Avouris, “Field-modulated carrier transport in carbon nanotube transistors”, Phys. Rev. Lett., vol. 89, pp. 126801/1-126801/4, 2002.
[2] J. Appenzeller, J. Knoch, V. Derycke, R. Martel, S. Wind, and P. Avouris, “Short-channel like effects in Schottky barrier carbon nanotube field-effect transistors”, in Proc. IEDM 2002, pp. 285-288.
[3] P. Avouris, J. Appenzeller, R. Martel, and S. J. Wind, “Carbon nanotube electronics”, Proceedings of the IEEE, 2003.
[4] A. Bachtold, P. Hadley, T. Nakanishi, and C. Dekker, “Logic circuits with carbon nanotube transistors”, Science, vol. 294, pp. 1317-1320, 2001.
[5] A. Cassel, N. Franklin, T. Tombler, E. Chan, J. Han, and H. Dai, “Current directed growth of free-standing single-walled carbon nanotubes”, J. Amer. Chem. Soc., vol. 121, pp. 7975-7976, 1999.
[6] P. G. Collins and P. Avouris, “Nanotubes for electronics,” Sci. Amer., vol. 283, pp. 38-45, 2000.
[7] P. S. Damle, A. W. Ghosh, and S. Datta, “First principles analysis of molecular conduction using quantum chemistry software”, Chem. Phys. 281, 171 (2002).
[8] P. S. Damle, A. W. Ghosh, and S. Datta, “Unified description of molecular conduction—from molecules to metallic wires”, Phys. Rev. B 64, 201403R (2001).
[9] S. Datta, “electronic Transport in Mesoscopic Systems”, Cambridge Studies in Semiconductor Physics and Microelectronic Engineering, New Ed edition (1997).
[10] S. Datta, “Quantum Transport: Atom to Transistor”, Cambridge University Press; 2Rev Ed edition (2005).
[11] V. Derycke, R. Martel, J. Appenzeller, and P. Avouris, “Controlling doping and carrier injection in carbon nanotube transistors”, Appl. Phys. Lett., vol. 80, pp. 2773-2775, 2002.
[12] M. S. Dresselhaus, G. Dresselhaus, and P. Avouris, “Ed. Carbon Nanotubes: Synthesis, Structure Properties, and Applications”, Berlin, Germany: Springer-Verlag, 2001.
[13] S. Frank, P. Poncharal, Z. L. Wang, and W. A. de Heer, “Carbon nanotube quantum resistors”, Science, vol. 280, pp. 1744-1746, 1998.
[14] A. W. Ghosh, P. S. Damle, S. Datta, and A. Nitzan, “Molecular electronic Devices”, MRS Bulletin, 29, 391 (2004).
[15] A. W. Ghosh, T. Rakshit, and S. Datta, “Gating of a molecular transistor—electrostatic and conformational”, Nano Lett. 4, 565 (2004).
[16] A. Ghosh and M. Stan, “Electrical characteristics of graphene ribbons”, unpublished.
[17] D. Gunlycke, H. M. Lawler, and C. T. White, “Room temperature ballistic transport in graphene nanostrips”, Arxiv preprint cond-mat/0606693, 2006-arxiv.org.
[18] J. Guo, S. Goasquen, M. Lundstrom, and S. Datta, “Metal-insulator-semiconductor electrostatics of carbon nanotubes”, Appl. Phys. Lett., vol. 81, pp. 1486-1488, 2002.
[19] J. Hass, C. A. Jeffrey, R. Feng, T. Li, X. Li, Z. Song, C. Berger, W. A. de Heer, P. N. First, and E. H. Conrad, “Highly-ordered graphene for two-dimensional electronics”, Appl. Phys. Lett. 2006.
[20] S. Heinze, J. Tersoff, R. Martel, V. Derycke, J. Appenzeller, and P. Avouris, “Carbon nanotubes as Schottky barrier transistors”, Phys. Rev. Lett., vol. 89, pp. 106801/1-106801/4, 2002.
[21] S. Iijima, “Helical microtubes of graphitic carbon”, Nature, vol. 354, pp. 56-58, 1991.
[22] “International Technology Roadmap for Semiconductors”, ITRS, available at www.itrs.net.
[23] A. Javey, Q. Wang, A. Urai, Y. In, and H. Dai, “Carbon nanotube transistor arrays for multi-stage complementary logic and ring oscillators”, Nano Lett. Vol. 2, pp. 929-932, 2002.
[24] D. Kienle, J. I. Cerda, and A. W. Ghosh, “Extended Huckel theory for bandstructure, chemistry and transport, Part I: Carbon Nanotubes”, J. Appl. Phys. 100, 043714 (2006).
[25] D. Kienle, J. I. Cerda, K. H. Bevan, G. Liang, L. Siddiqui, and A. Ghosh, “Extended Huckel theory for bandstructure, chemistry and transport, Part II: Silicon”, Arxiv preprint cond-mat/0603393, 2006.
[26] Y. Kobayashi, K. Fukui, T. Enoki, and K. Kusakabe, “Observation of zigzag and armchair edges of graphite using scanning tunneling microscopy”, Physical Review B, 2005.
[27] G. C. Liang and A. W. Ghosh, “Identifying contact effects in electronic conduction through C60 on silicon”, Phys. Rev. Lett. 95, 076403 (2005).
[28] G. C. Liang, D. Kienle, S. Patil, J. Wang, A. W. Ghosh, and S. Khare, “Impact of structure relaxation on the performance of small diameter, n-type <110> Si-Nanowire FETs”, IEEE-TNT, accepted.
[29] R. Martel, H. S. P. Wong, K. Chan, and P. Avouris, “Carbon nanotube field-effect transistors for logic applications”, in Proc. IEDM 2001, 2001, pp. 159-161.
[30] K. Nakada, M. Fujita, G. Dresselhaus, and M. S. Dresselhaus, “Edge state in graphene ribbons: Nanometer size effect and edge shape dependence”, Physical Review B, 1996-APS, available at http://www.nanohub.org/simulation_tools/huckel-iv_tool_information.
[31] Y. Niimi, T. Matsui, H. Kambara, K. Tagami, and T. Tsukada, “Scanning tunneling microscopy and spectroscopy studies of graphite edges”, Arxiv preprint physics/0404069, 2004.
[32] B. Obradovic, R. Kotlyar, F. Heinz, and P. Matagne, “Analysis of graphene nanoribbons as a channel material for field-effect transistors”, Applied Physics Letters, 2006.
[33] N. M. R. Perese, A. H. C. Neto, and F. Guinea, “Conductance quantization in mesoscopic graphene”, Arxiv preprint cond-mat/0512476, 2005 (arxiv.org).
[34] A. Rahman, M. S. Lundstrom, and A. W. Ghosh, “Generalized effective-mass approach for n-type metal-oxide-semiconductor field-effect transistors on arbitrarily oriented wafers”, J. Appl. Phys. 97, 053702 (2005).
[35] Z. Ren, R. Venugopal, S. Goasguen, Supriyo Datta, and Mark S. Lundstrom, “NanoMOS 2.0: A Two-Dimensional Simulator for Quantum Transport in Double-Gate MOSFETs”, IEEE Trans. Electron Devices, 50:1914-1925, 2003.
[36] L. Siddiqui, A. W. Ghosh, and S. Datta, “Phonon runaway in suspended nanotube quantum dots”, cond-mat/0606273.
[37] T. Rakshit, G. C. Liang, A. W. Ghosh, M. C. Hersam, and S. Datta, “Molecules on silicon: self-consistent first principles theory and calibration to experiments”, Phys. Rev. B 72, 125305 (2005).
[38] Garrett Rose, Adam C. Cabe, Nadine Gergel-Hackett, Nabanita Majumdar, Mircea R. Stan, John C. Bean, Lloyd R. Harriott, Yuxing Yao, and James M. Tour, “Design Approaches for Hybrid CMOS/Molecular Memory based on Experimental Device Data”, Great Lakes Symposium on VLSI (GLSVLSI), May 2006, Best paper award.
[39] Garrett Rose, Matthew Ziegler, and Mircea Stan, “A Large-Signal Two-Terminal Device Model for Nanoelectronic Circuit Analysis”, IEEE Transactions on VLSI Systems, vol. 12, issue 11, pp. 1201-1208, November 2004.
[40] Garrett S. Rose and Mircea R. Stan, “Memory arrays base don molecular RTD devices”, Proceedings of the IEEE Conference on Nanotechnology (IEEE-NANO), pp 453-456, San Franscisco, Calif., August 2003.
[41] S. Sasaki, S. Murakami, and R. Saito, “Stabilization mechanism of edge states in graphene”, Applied Physics Letters, 2006.
[42] F. L. Shyyu, M. F. Lin, C. P. Chang, R. B. Chen, and J. C. Shyu, Y C, “Tight-Binding Band Structures of Nanographite Multiribbons”, Journal of the Physical Society of Japan, 2001.
[43] F. L. Shyyu and M. F. Lin, “Electronic properties of AA-stacked nanographite ribbons”, Physica E: Low-Dimensional Systems and Nanostructures, 2003—Elsevier.
[44] S. Souma, T. Yamamoto, and K. Wantanabe, “Electronic Transport Properties of Graphitic Ribbons Under Finite Bias Voltages”, e-Journal of Surface Science and Nanotechnology, 2006—J-STAGE.
[45] Mircea R. Stan, Garrett Rose, and Matthew Ziegler, “Hybrid CMOS/Molecular Integrated Circuits”, book chapter in “Moore's Law: Beyond Planar Silicon CMOS and Into the Nano Era”, Springer Verlag, Howard Huff editor, to appear 2007.
[46] Mircea R. Stan, Hybrid CMOS/Molecular Electronic Circuits”, Proceedings of the IEEE Nano Singapore Conference, Singapore, January 2006.
[47] Mircea R. Stan, Garrett Rose, and Matthew Ziegler, “Hybrid/CMOS/Molecular Electronic Circuits”, Proceedings of the International Conference on VLSI Design, Hyderbad, India, January 2006.
[48] Mircea R. Stan, Paul Franzon, Seth Goldstein, John Lach, and Matthew Ziegler, “Molecular Electronics: from devices and Interconnect to Circuits and Architecture”, Proceedings of the IEEE, vol. 91, issue 11, pp. 1940-1957, November 2003.
[49] A. J. Stone and D. J. Wales, Chem. Phys. Lett. 128 501, 1986.
[50] S. Tans, S. Verschueren, and C. Dekker, “Room-temperature transistor based on single carbon nanotube”, Nature, vol. 393, pp. 49-52, 1998.
[51] Y. Zhang, A. Chang, J. Cao, Q. Wang, W. Kim, Y. Li, N. Morris, E. Yenilmez, J. Kong, and H. Dai, “Electric-field-directed growth of aligned single-walled carbon nanotubes”, Appl. Phys. Lett., vol. 79, pp. 3155-3157, 2001.
[52] Matthew Ziegler and Mircea Stan, “CMOS/nano Co-design for crossbar-based molecular electronic systems”, IEEE Transactions on Nanotechnology, vol. 2, issue 4, pp. 217-230, Dec. 2003.
[53] Matthew M. Ziegler and Mircea R. Stan, “The CMOS/nano Interface from a Circuits Perspective”, Proceedings of the International Symposium on Circuits and Systems (ISCAS), Bangkok, Thailand, May 2003.
[54] Matthew M. Ziegler and Mircea R. Stan, “A Case for CMOS/nano Co-design”, Proceedings of the International Conference on Computer Aided Design (ICCAD), San Jose, Calif., November 2002.
[55] Matthew M. Ziegler and Mircea R. Stan, “Design and Analysis of Crossbar Circuits for Molecular Nanoelectronics”, Proceedings of the IEEE Conference on Nanotechnology (IEEE-NANO), Arlington, Va., August 2002.
[56] Matthew M. Ziegler, Garrett S. Rose, and Mircea R. Stan, “A Universal Device Model for Nanoelectronic Circuit Simulation”, Proceedings of the IEEE Conference on Nanotechnology (IEEE-NANO), Arlington, Va., August 2002.
[57] S. Vasudevan, K. Walczak, and A. W. Ghosh, “Physics of trap-assisted molecular conduction”, unpublished.
[58] K. Wakabayashi, M. Fujita, H. Ajiki, and M. Sigrist, “Electronic and magnetic properties of nanographite ribbons”, Physical review B, 1999.
[60] R. Waser, Nanoelectronics and Information technology”, Wiley VCH, 2005.
[61] B. Obradovic et al., “Carbon nanoribbons: An Alternative to Carbon Nanotubes”, IEEE 2006.
[62] U.S. Pat. No. 7,015,142 B2 to Walt E. de Heer et al., “Patterned Thin Film Graphite Devices and Method for Making Same”, Mar. 21, 2006.
[63] C. Berger, S. Song, I. Li, X. Li, A. Y. Ogbazghi, R. Feng, Z. Dai, A. Marchenkov, E. Conrad, P. First, and W. de Heer. Journal of Phys. Chem., 108, 19912 (2004).
[64] K. Nakada, M. Fujita, G. Dresselhaus, and M. Dresselhaus, Physical review B, 54, 17954 (1996).
[65] R. Saito, G. Dresselhaus, and M. Dresselhaus, “Physical Properties of Carbon nanotubes”, Imperial College Press, London (2003).
[66] R. Kotlar, B. Obradovic, P. Matagne, M. Stettler, and M. Giles, Applied Physics Letters, 84, 5270 (2004).
[67] J. Y. Park, S. Rosenblatt, Y. Yaish, V. Sazonova, H. Ustunel, S. Braig, T. A. Arias, P. W. Brouwer, and P. I. McEuen, Nano Letters, 4, 517 (2004).
[68] G. Pennington and N. Goldsman, Physical Review B, 68, 045426 (2003).
[69] Y. Li, S. V. Rotkin, and U. Ravaioli, Nano Letters, 3, 183 (2003).
[70] B. Obradovic, R. Kotlyar, F. Heinz, P. Matagne, I. Rakshit, D. Nikonov, M. Giles, and M. Stettler, Applied Physics Letters, 88, 142102 (2006).

### BRIEF SUMMARY OF THE INVENTION

An aspect of various embodiments of the present invention comprises, but is not limited to, graphene sheets patterned into ribbons of given widths and at given angles (with respect to the two-dimensional graphene hexagonal lattice). Such graphene nanoribbons (GNRs) have either metallic or semiconductor behavior, depending on their dimensions and orientation to the hexagonal graphene lattice.

A second aspect of various embodiments of the present invention comprises, but is not limited to, using combinations of such GNRs of various dimensions and angles in order to create circuits formed of devices and interconnects that intrinsically have no interface defects as they are pattered from the same two-dimensional graphene sheet.

A third aspect of the present invention provides, among other things, the design of graphene-ribbon circuits in which the devices are arranged in plane such that metallic and semiconductor alternate in order to create the desired circuit behavior. For example, a metallic ribbon can be used as a wire, two semiconductor ribbons in parallel can create an OR function, two in series can create an AND function, etc.

A fourth aspect of various embodiments of the present invention comprises, but is not limited to, the use of various passivating elements at the edges in order to modulate conduction properties, as well as the use of gating structures in order to turn the devices on and off by the use of voltages. The undoped graphene devices are intrinsically ambipolar; however, the desired NMOS- or PMOS-like asymmetric behavior can be obtained by shifting the Fermi level of the channel region by using metals with specific workfunctions for the gate or by doping chemically, electrostatically, or by other means.

A fifth aspect of various embodiments of the present invention is that the principles described herein can be applied to myriad electronic structures such as, but not limited to, multi-ribbon structures alternating metallic and semiconductor behavior in order to obtain combined wire/device structures with no interface defects. Such structures are created by patterning a single planar graphene sheet, a technique that has not been investigated until now. The idea of using different elements for passivating the ribbon edges in order to tune ribbon behavior has also not been investigated until now.

### BRIEF DESCRIPTION OF THE DRAWINGS

FIG. 1 shows a) the energy-band structure for graphene, b) the primitive cell (rhombic) and the unit cell (rectangular) lattice in real space, and c) the lattice in reciprocal space (see Background reference [30]).

FIG. 2 shows a planar grapheme sheet with various chiral vectors.

FIG. 3 shows a) a (4,2) chiral semiconductor CNT and b) a (3,3) armchair metallic CNT (from Background reference [3]).

FIG. 4 shows graphene ribbons: a) armchair edge, b) zigzag edge, and c) jagged edge (from Background reference [30]).

FIG. 5 shows simple graphene ribbon wires (a, b, and c), graphene ribbon junctions (c, d, e, f, g, h, I, and j), and gated graphene ribbon junctions (k), including parallel (l) and series (m).

FIG. 6 shows a gated three-segment graphene ribbon junction (see also FIG. 7(k)) showing the hexagonal lattice.

FIG. 7 shows a section of GNR (or CNR), with points representing atoms of carbon. Only one unit cell is actually simulated, with periodic boundary conditions applied in the transport direction (CNT also has periodic boundary conditions applied along the edge).

FIG. 8 shows a top-down schematic of a GNR (or CNR) transistor, with GNRs (or CNRs) forming both channel and S/D regions.

FIG. 9 shows the GNR (or CNR) (top) and CNT (bottom) electron bandstructures are shown, for the (10,0) chirality.

FIG. 10 shows the dependence of bandgap on ribbon/tube size for GNRs (or CNRs) and CNTs.

FIG. 11 shows a schematic of ground-state wave functions in GNRs (or CNRs) (terminating) and CNTs (periodic).

FIG. 12 shows the phonon dispersion relations for a (7,0) CNT (left) and (7,0) GNR (or CNR) (right) in the first Brillouin zone. The lowest energy modes are similar, degeneracy lifting and energy reduction is evident for the higher modes.

FIG. 13 shows the third and fourth phonon modes of the (7,0) GNR (or CNR). Note that the fourth (out-of-plane) mode clearly has non-periodic boundary conditions, not possible in the CNT.

FIG. 14 shows a comparison of CNT and GNR (or CNR) mobilities. All structures are semi-conducting unless otherwise indicated.

FIG. 15 shows a comparison of CNT and GNR (or CNR) mobilities versus lateral field (from Monte Carlo, similar to the approach discussed in Background reference [68]). At matched size, GNR (or CNR) low-field mobility is higher, but the high-field degradation starts at lower field values.

FIG. 16 shows a comparison of GNR (or CNR) and CNT mobilities at matched bandgap. Due to the reduced GNR (or CNR) bandgap, CNTs have considerably higher mobilities at matched bandgap.

### DETAILED DESCRIPTION

Note: Some of the References Listed in the Background Section are Referred to in this Description Using the Reference Number

### First Embodiment

### Application of Graphene Nanoribbons to Electronic Devices

### Introduction

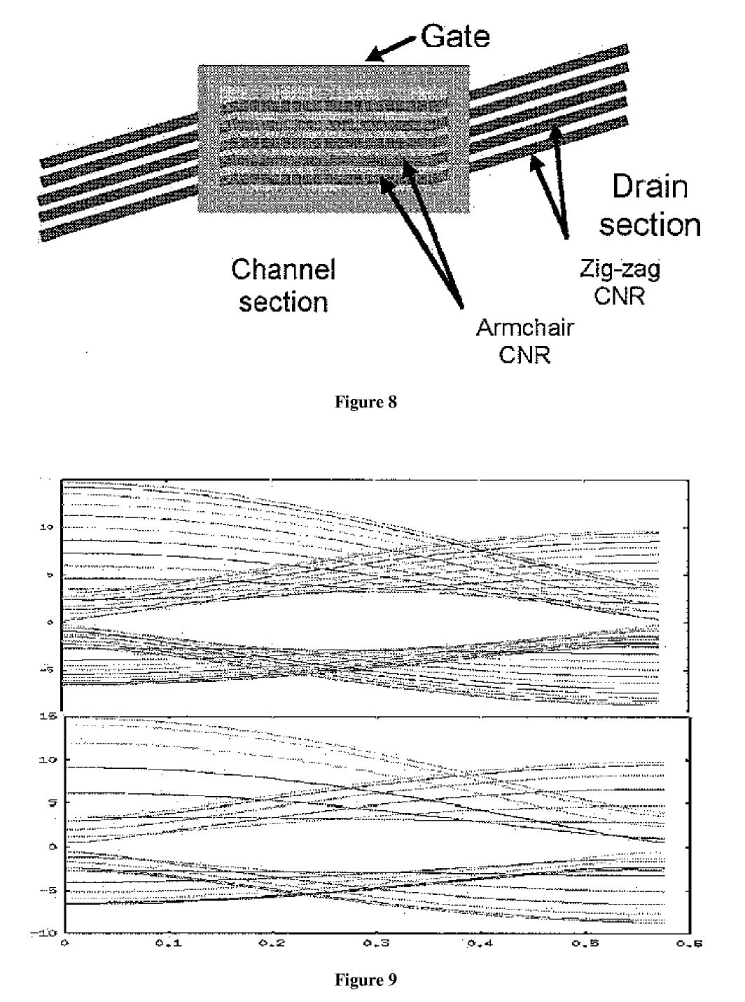

Graphene nanoribbons (GNRs), a term intended in this specification to encompass carbon nanoribbons (CNRs), are essentially a monolayer of graphite patterned into a narrow strip, and have recently been proposed as an attractive alternative to carbon nanotubes (CNTs) (see Background reference [63]). While CNTs have many highly desirable electronic properties (such as exceedingly high mobility and potentially excellent short channel effects in field-effect transistors (FETs) due to a small “depth”/length aspect ratio), no method of assembling large-scale circuits comprised of CNTs has yet been devised. The main difficulty is that CNTs are created prior to integration and need to be placed in correct positions in the circuit. This is contrary to the conventional planar process in silicon, in which devices are formed on the entire wafer at once by lithographic means. GNRs offer the promise of lithographic patternability, while providing electronic properties similar to those of CNTs. Furthermore, the electronic properties of GNRs are lithographically tunable, selecting metallic vs. semiconducting GNRs, by the orientation of the edge termination (for a semiconducting armchair GNR, see FIG. 7). Moreover, the electronic properties of GNRs are also dependent on GNR width, where a width of 10 nm or less yields semiconducting properties and a width of greater than 10 nm yields metallic properties. Thus, the channel, source and drain regions are formed by a single patterning step, requiring only the addition of the gate stack and contacts to complete the transistor. A schematic of such a transistor is shown in FIG. 8. The required sizes and orientations result from the basic GNR properties, as discussed in this embodiment.

### Basic GNR Electronic Properties

GNRs have electrical characteristics that are quite similar to CNTs (and thus, exhibit good performance). However, being planar, GNRs can be patterned using more standard semiconductor industry fabrication methods. This way, using GNRs can bypass the alignment problem that CNTs face, and in addition, GNRs can control the ribbon orientation (and thus, its metallicity). In contrast, CNT chiralities are predetermined statistically during the manufacture process and have been near impossible to control. This embodiment targets combinations of ribbons of various dimensions, of various orientations, and in various arrangements (thus, behaving as either metal or semiconductor, with or without gating) in order to obtain circuit elements and devices that can be used for more complex circuits, such as logic gates and memory elements.

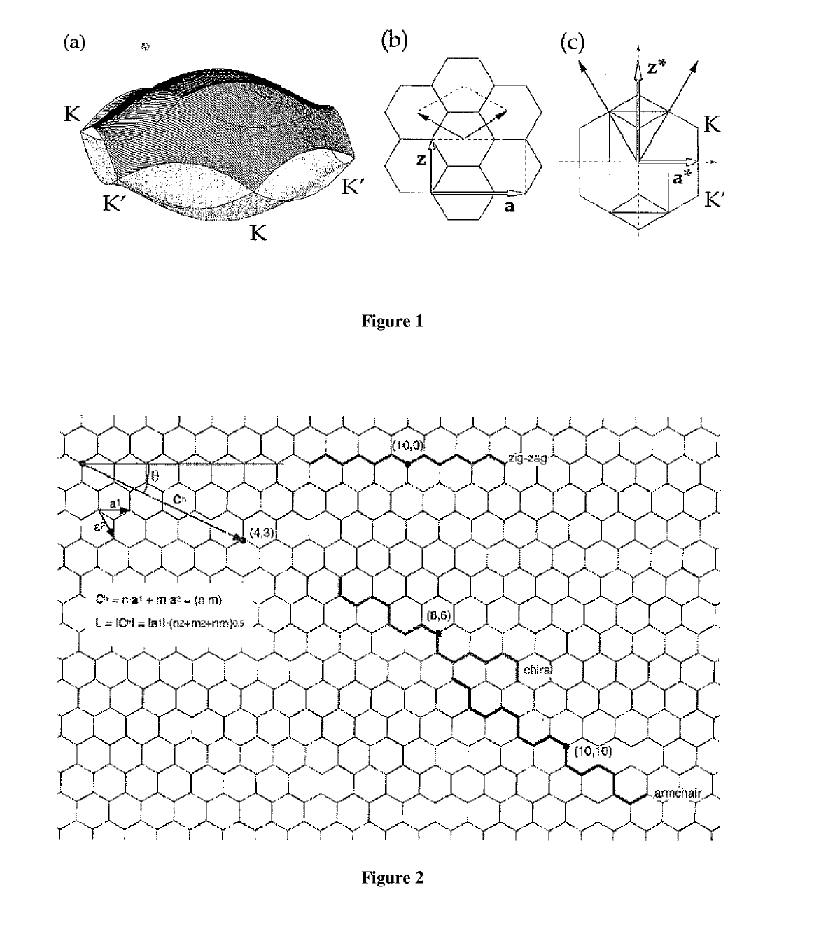

Graphene, a single sheet of graphite, is a two-dimensional (2D) carbon system arranged in a hexagonal (also known as honeycomb) lattice. The carbon atoms in graphene are sp² hybridized and have strong links with their three nearest neighbors. The 2p_{z} atomic orbitals (AOs) of adjacent atoms in the graphene sheet overlap and form bonding (π-band) and anti-bonding (π*-band) 2D bands. FIG. 1 shows a) the energy-band structure for graphene, b) the primitive cell (rhombic) and the unit cell (rectangular) lattice in real space, and c) the lattice in reciprocal space (see Background reference [30]). Note that FIG. 1(c) is also known as the first Brillouin zone for graphene. As can be seen, the valence and conduction bands make contact at the degeneracy point K. Thus, graphene can be considered a zero-bandgap semiconductor (also called semi-metallic).

The band diagram of the 2D graphene is relevant for understanding CNTs, except that due to the small diameter of the tube, the CNT becomes a quasi one-dimensional system and the energy levels are quantized in the transversal direction. There are many ways in which the graphene sheet can be rolled to form a CNT, but they all can be described by the use of just two numbers. Assume a graphene sheet with the lattice arranged as in FIG. 2. When a ribbon of the sheet is rolled to form a CNT, one site (carbon atom) on one edge will be crystallographically equivalent to another site on the other edge. This equivalence can be captured in a circumference chirality vector C=na₁+ma₂, where n and m are integers and a₁ and a₂ are unit vectors of the hexagonal lattice. FIG. 2 shows the two unit vectors a₁ and a₂, and several example chiral vectors, including (4,3), (8,6), (10,0), and (10,10). From FIG. 2, it can be seen that some chiral vectors have distinguishing features: In particular, the chiral vectors of the form (n,0) or (0,m), which are called “zigzag” due to their shape, and also, the chiral vectors of the form (n,n), which are called “armchair”. All other vectors are simply called “chiral”.

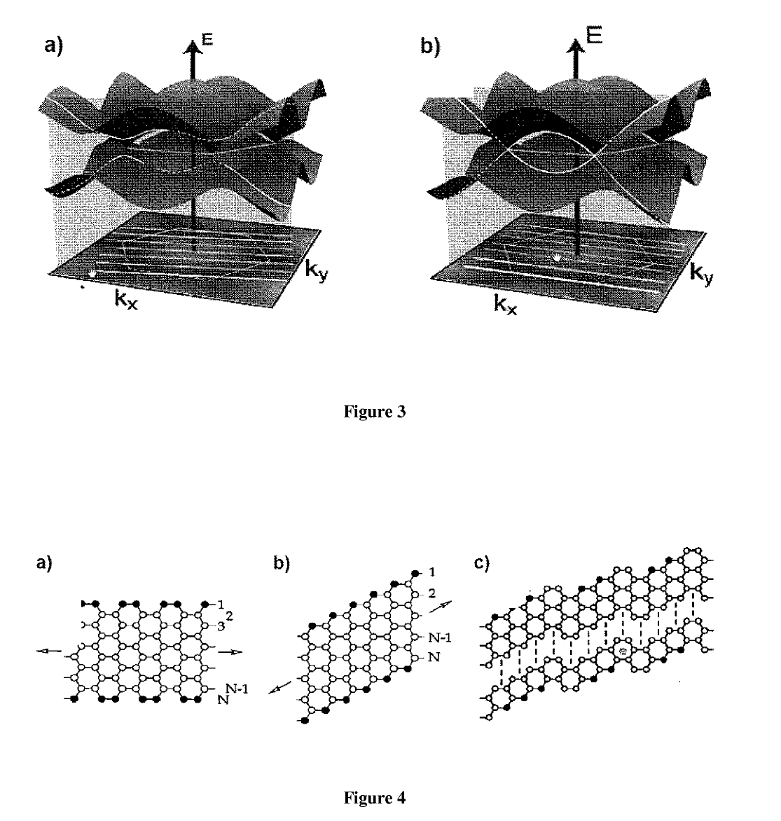

The chiral vector determines the way that the energy levels are quantized in the CNT, and the interaction between this quantization and the energy bands of the graphene determines the electrical characteristics of the CNT. FIG. 3 shows the projection of the allowed states of CNTs on the energy bands of graphene for two different types of CNTs: a chiral (4,2) and an armchair (3,3) (see Background reference [3]). As can be seen from FIG. 3, the allowed states intersect the degeneracy K points of the Brillouin zone for the (3,3) tube, but fall in between the K points for the (4,2) chiral tube. By imposing periodic boundary conditions in the circumferential direction, it can be shown that the allowed modes are such that for any (n,m) tube where n−m is a multiple of 3, the tube will have zero bandgap. For all other cases, the tube will have a non-zero bandgap. (See Background references [1] and [2]). This means that the armchair (3,3) tube will have a zero bandgap and will be metallic, while the (4,2) tube will have a non-zero bandgap and will be semiconductor. In general, all armchair tubes will be metallic, while one-third of all zigzag tubes will have zero bandgap and the two-thirds will be semiconductor.

The bandstructure of GNRs is computed using the conventional nearest neighbor Tight-Binding method, with a p_{z}-orbital-derived Bloch wavefunction basis, similar to the method frequently used for CNTs (see Background references [64] and [65]). The overlap element is retained, resulting in the generalized Eigen problem. The p_{z} basis is sufficient even for narrow ribbons, since the small-curvature approximation usually made for CNTs is strictly valid for GNRs. The absence of curvature implies that the p_{z} portion of the TB Hamiltonian is decoupled from the sp² in-plane part, and can be treated separately. Since the bottom of the conduction band and the top of the valence bands are formed using precisely the p_{z} set of states, which are in turn decoupled from the rest of the Hamiltonian, only the p_{z} portion is used for computations. The key ingredient for GNR computation is the treatment of the boundary conditions. Whereas the CNT has periodic boundary conditions in both the transport and “width” directions, the GNR has periodic boundary conditions only in the transport direction. No special boundary condition is asserted on the wavefunctions in the transverse directions; the edge atoms are simply assumed to have fewer coupling neighbors. In order to facilitate computations with this boundary condition, the zone-folding approach is not used, resulting in a larger (but still quite manageable) Eigenvalue problem. Note that this approximation ignores the interaction of the carbon atoms with the Si—C substrate (used to form the graphene layer), which is assumed here to be weak.

Computed GNR bandstructures are shown in FIG. 9. There are obvious qualitative similarities: Both metallic and semiconducting bandstructures are manifested. The semiconductor bandgap depends on the size, shape, and angle of the structure, and the conduction and valence bands are not symmetric (due to the inclusion of the overlap parameter).

There are also notable difference between CNTs and GNRs, however. Firstly, the two-fold degeneracy of the CNT states is removed—the lowest subband of the conduction and valence bands are nondegenerate in the GNR. Secondly, the lowest subband of the GNR has appreciably higher curvature than the corresponding CNT subband (for the semiconducting cases).

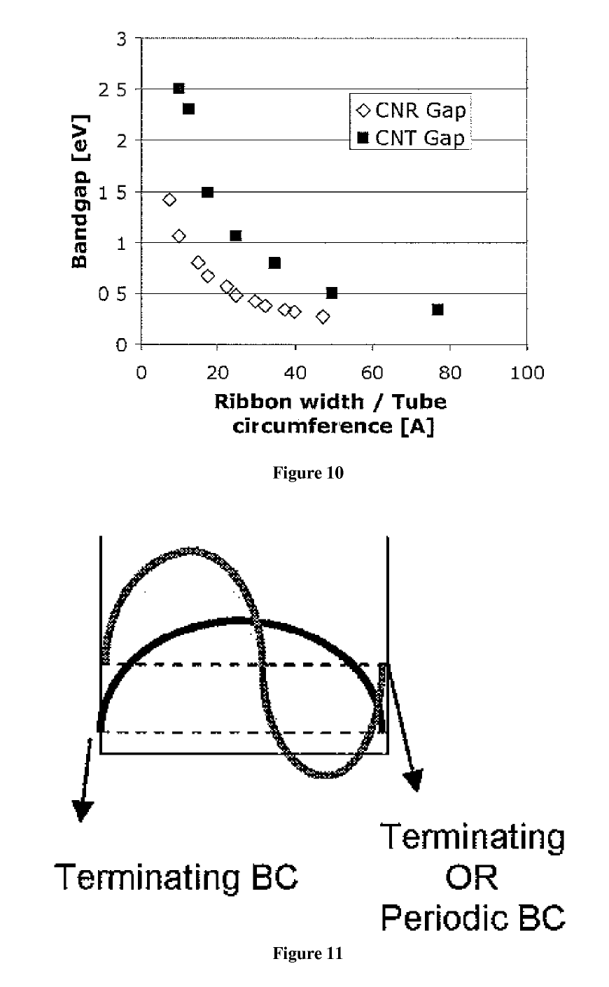

The most striking difference between the CNT and GNR bandstructures, however, is the much-smaller bandgap of the GNRs. This is illustrated in FIG. 10, where the bandgap of GNRs (CNRs) and CNTs is shown as a function of size. The much-smaller CNT bandgap can be easily understood qualitatively, as shown schematically in FIG. 11. The electronic wavefunctions of CNTs must obey periodic boundary conditions (PBCs), matching both the value and slope at the tube “edge”. Thus, the lowest energy state must have the qualitative shape of the sinusoidal wavefunction in FIG. 11. The GNR has no such restriction, and consequently permits a wavefunction qualitatively similar to the semi-circular curve in FIG. 11. The later will obviously have lower energy (the reduced curvature results in a lower expectation value for kinetic energy). Therefore, the GNR permits states lower in energy than the CNT. This is a basic property of periodic vs. non-periodic structures, and is not subject to modeling details.

The small bandgap of the GNR has important technological consequences, since it limits the band-to-band source-to-drain tunneling and ambipolar conduction (sufficiently short devices will be SD tunneling limited). As shown in FIG. 10, achieving Si-like bandgaps requires 1 nm or smaller GNRs, with 0.5 eV bandgaps achievable at ˜2 nm. Such minuscule sizes bring into question the feasibility of large-scale integration, possibly defeating the promise of lithographic patternability.

### GNR Vibrational Properties

Transport in a perfect GNR (or CNT, for that matter) will be determined by phonon scattering, since vibrational distortions of the lattice cannot be removed at finite temperature. The continuum approach of computing phonon dispersion relations becomes invalid for narrow structures; the length scale for lateral variations in the displacement field must be many atomic distances in size. This is a condition that is clearly violated for a structure that is only a few atoms across. Thus, an atomistic approach is needed.

The semi-classical force-constant method is employed, which is essentially an application of Newton's Second Law, with a tensorial force-constant coupling each atom pair (see Background reference [65]). The total force on any given atom is obtained by summing the contributions of all neighbors within a given radius (fourth-nearest neighbors are included). A propagating wave form of the solution is then assumed in the transport direction (one-dimensional transport and k-vector for the GNR and CNT), which leads to a generalized Eigenvalue problem for the frequency, at any given wave vector. The problem is then solved for a set of wavevectors in the Brillouin zone, resulting in the complete dispersion relation (phonon bandstructure). Furthermore, the eigenvectors (multiplied by the wavevector-dependent phase factor) represent the atomic displacements of the various modes. The treatment of the CNT and GNR is virtually identical; all atoms experience a force coupling to all neighbors within a fourth-nearest neighbor radius. For the CNT, this means that periodic boundary conditions are applied. For the GNR, the edge atoms simply have fewer coupled neighbors. No displacement boundary conditions are applied; these arise naturally from the solution of the Eigen problem. The force constants are assumed not to change near the edge of the ribbon. This is an approximation, of course, but a reasonable one for a first-order calculation. More-detailed calculations would need to comprehend the influence of the substrate, as well as any other surrounding topography.

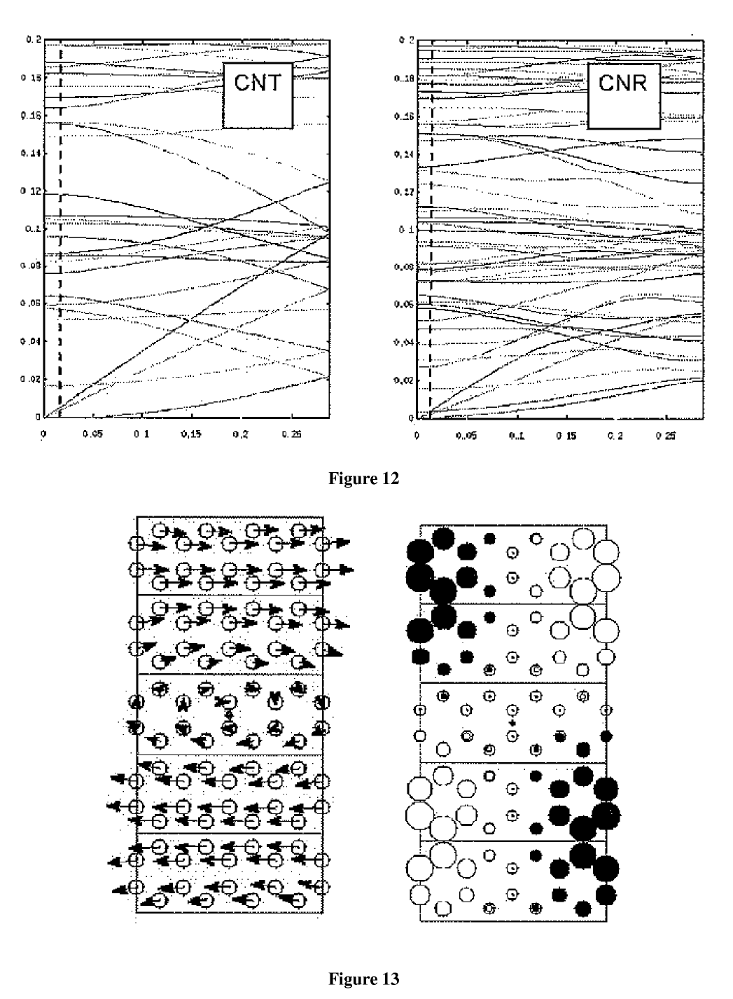

The resulting bandstructures for the GNR and CNT are shown in FIG. 12. While they appear quite different at first glance, there are notable similarities in the low-frequency acoustic modes. Specifically, the two in-plane modes (modes with linear dispersion relation near the origin of the plot) and the lowest frequency transverse mode (parabolic near the origin) are quite similar. Higher-order modes have reduces frequency and lifted degeneracy in the GNR. The similarities and differences of the two dispersion relations are best understood by examining the atomic displacements.

Since the force-constant tensor does not couple in-plane displacements with out-of-plane forces (and vice versa), the in-plane and out-of-plane motions are decoupled. Thus, modes are either entirely in-plane, or entirely out-of-plane. For the GNR, this arises naturally. For the CNT, it is due to the neglect of curvature. The second two modes of the GNR and CNT are shown in FIG. 13. The in-plane displacements are indicated by arrows, whereas out-of-plane displacements are indicated by discs. In the GNR, the absence of periodic boundary conditions in the lateral direction permits an additional degree of freedom for the atomic displacements of the edge atoms, which can move in opposite directions (this is not possible in CNTs). This results in additional phonon modes for the GNR.

### GNR Transport Properties

The key property that makes the CNT attractive for FET devices is its high mobility. While the GNR is qualitatively similar to the CNT, it is not necessarily clear that it will have similarly high mobility. The low-field phonon-limited mobility is computed for both the GNR and the CNT using the Born Scattering approach, similar to that outlined in Background references [67] and [68]. The overlap matrix elements are computed using direct integration of the previously computed electron and phonon wavefunctions. The selected rules are limited to forward momentum and conservation only (angular momentum would apply for the CNT as well, but not for the GNR). The overall mobility value is obtained using the Kubo-Greenwood formula.

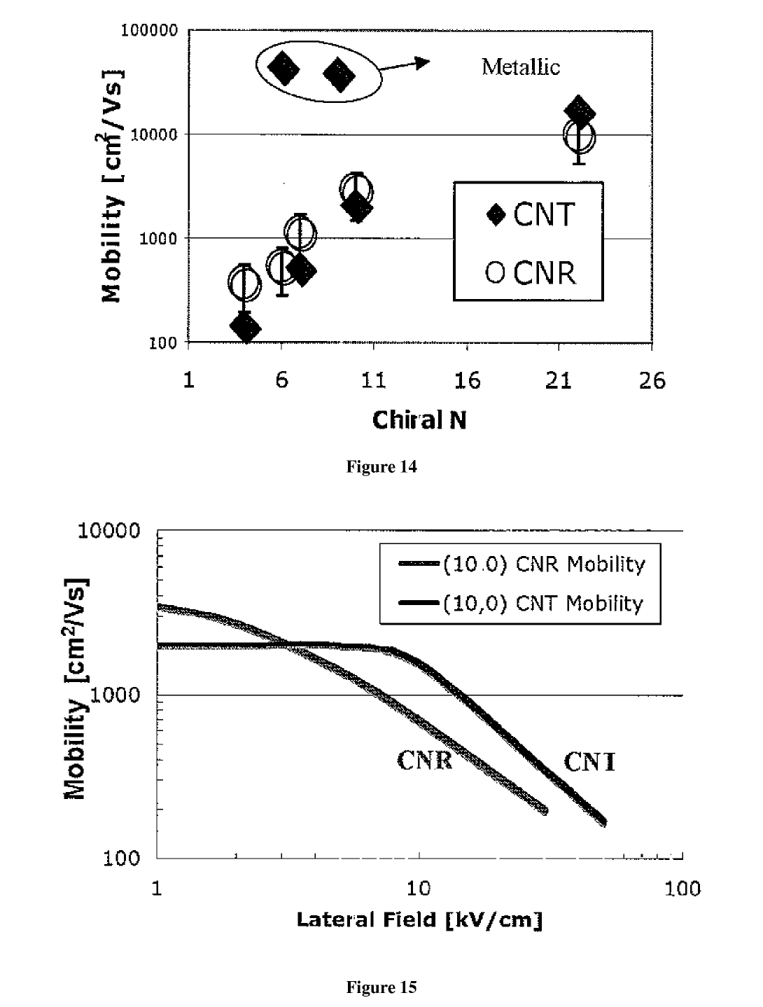

The results of the mobility computation as a function of GNR and/or CNT size are summarized in FIG. 14. As previously reported (both theoretically and experimentally), the CNT mobility degrades with decreasing CNT diameter. The GNR mobility behaves similarly, and the effect is understood as a consequence of increasing wavefunction confinement with decreasing size. Also apparent is the fact that the GNR mobility is in fact higher than the CNT mobility, at equal size (the perimeter of the CNT equals the width of the GNR). This can be primarily attributed to the significantly smaller transport effective mass of the GNR. As previously discussed, the GNR has a lower-energy/higher-velocity ground state than the CNT. The phonon modes primarily responsible for low-field mobility are quite similar between the GNR and the CNT; therefore, the phonon modes are not a significant differentiator between the GNR and the CNT.

The mobility shown in FIG. 14 corresponds to the low-vertical field mobility. In general, it is expected that the phonon-limited mobility is strongly modulated by the vertical field, as evidence by the inversion layer of the planar MOSFET, Si nanowire, or FinFET device. The CNT and GNR, however, exhibit a very weak field dependence of mobility, with a nearly constant mobility from 0 field to the MV/cm field range. The mobility does not change significantly until the vertical field approaches the 10 MV/cm range. Given that the primary reason for the field-induced variation of inversion layer is the modulation of the spatial confinement of the carriers, it is not surprising that the CNTs and GNRs show very little field dependence. Their out-of-plane confinement is essentially unchanged with the applied field. This intuitive assertion is supported by field-dependent bandstructure calculations (see Background reference [69]).

Whereas the vertical electric field has little influence on the bandstructure and mobility of GNRs and CNTs, the lateral field modulates it quite strongly. This is quantified using the Monte Carlo method, and the results are shown in FIG. 15. The behavior of the CNT mobility has already been reported in Background reference [68], where scattering from the conduction-band ground state to the first excited state resulted in mobility degradation, at a faster rate than what scattering-limited velocity saturation would predict. The GNR behavior is very similar, with the electron transfer to higher subbands occurring at lower energies, and the mobility consequently degrading at lower fields.

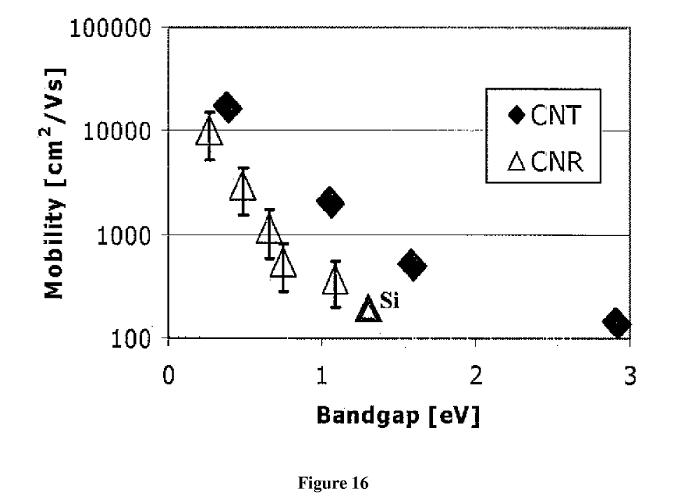

While the equal-size mobility of the GNR is higher than that of the CNT, it is perhaps more meaningful to compare the mobilities at equal bandgaps. The size of the bandgap determines the available range of voltages for a device operating in the ambipolar mode, as well as determines the ultimate limit for device scaling due to S/D tunneling. This comparison is illustrated in FIG. 16. This implies that the GNR is operating with stronger lateral confinement, which overwhelms the superior group velocity of the smaller GNR. As the bandgap approaches 0 (graphene), the mobilities of the GNR and the CNT become similar. However, at more-technologically relevant bandgaps of >0.5 eV, the GNR mobility is hardly superior to that of Si. The nearly ballistic regime often cited for CNTs is available to GNRs only for bandgaps <0.25 eV.

GNRs vs. CNTs

Since many of the characteristics of CNTs stem from the underlying graphene lattice, the electrical characteristics of a CNT will be maintained even when the CNT is unrolled into the equivalent ribbon (which can be thought of as the planarized outer shell of the CNT) (see Background reference [16]). The softer edge boundary conditions on the ribbon, instead of more stringent periodic boundary conditions around the nanotube circumference, lower the graphene bandgap, but preserve its overall chiral properties (see Background reference [32]). A first-order analysis of graphene ribbons can follow almost the same methodology as that as CNTs. A two-dimensional (2D) graphene hexagonal lattice can be patterned into narrow ribbons that will create a quasi one-dimensional (1D) system with quantized states in the transversal direction. Two such 1D ribbons are shown in FIG. 4 (also, see Background reference [30]).

The reader is cautioned to note that the nomenclature used in the literature for graphene nanoribbons (GNRs) is unfortunately exactly the opposite as for CNTs. For example, the GNR in FIG. 4(a) is called an armchair-edge ribbon, and a simple inspection confirms that (if rolled into a CNT) this corresponds to a zigzag circumference CNT. Similarly, the zigzag-edge ribbon in FIG. 4(b) can be seen to correspond to an armchair circumference CNT.

CNTs have been experimentally produced in the lab and their measured results have shown excellent characteristics for electronic applications (see Background reference [12]). The measured characteristics of CNTs include:
High carrier mobility (see Background reference [6]);
Allowance of high current densities;
Capable of being doped both n-type and p-type (see Background reference [11]); and
Almost perfect electrostatic properties, having been used for field-effect transistors with excellent characteristics (see Background references [18], [1], and [23]).

However, there are two major roadblocks in trying to use CNTs for any practical applications: Until now, there have been no credible solutions for arranging large numbers of CNTs on a substrate in order to integrate them into a circuit, and there have been no clear solutions for controlling their chirality during synthesis. Most of the experiments until now have consisted of the tedious manual selection of individual CNTs from a large number of synthesized CNTs with chiralities statistically distributed, followed by the manual arrangement of one or a small number of such CNTs in-situ (see Background references [5] and [51])). However, controlling the tubes chirality is an on-going effort, and the results until now have been unsatisfactory to the point where one can raise serious doubts that CNTs will ever be usable on a large scale as electronic devices.

### Application of Graphene Nanoribbons in Electronic Devices

This embodiment describes a direct relationship with work on CNTs and work on graphene done elsewhere. Between the two, the work on CNTs is much more mature. The work done on CNTs elsewhere includes:
Fabrication (see Background references [21], [5], [11], [12], and [51]);
Device characterization (see Background references [1], [2], [3], [13], [20], and [50]);
Logic-circuit design (see Background references [23] and [29]); and
Device modeling (see Background references [24], [25], and [26]).

The fabrication aspects of CNTs and GNRs is quite different, but all the other efforts, including device modeling and characterization, and including logic-circuit design, have many similarities and the present invention takes full advantage of those. The work on graphene done elsewhere includes:
Fabrication (see Background reference [19]);
Ribbon-edge passivation (see Background reference [41]);
Ribbon-edge characterization (see Background references [31], [32], and [26]); and
Modeling (see Background references [58], [42], [43], [33], [32], and [43]).

In the present invention, graphene sheets are patterned into ribbons of given width and at given angle with respect to the two-dimensional hexagonal (honeycomb) lattice. Such GNRs have either metallic or semiconductor behavior depending on their general shape, specific dimensions, and orientation to the hexagonal graphene lattice.

The present invention discloses that GNRs can be used for building devices, wires, and circuits by patterning graphene using planar techniques in order to create metallic ribbons (wires and electrodes) and semiconductor ribbons (devices), of given width, angle, and shape, out of one template.

Being made out of a continuous graphene sheet such structures should exhibit no heptagon-pentagon Stone-Wales defects as in CNTs with junctions (see Background reference [49]). This means that the contact-channel interfaces are likely to be ohmic contacts rather than Schottky contacts. By using planar-patterning techniques, the alignment problem of nanotubes is implicitly solved. Likewise, the use of planar techniques also implicitly solves the chirality control problem. Since such GNRs have no top-dangling bonds, it means that such GNRs will allow high-k dielectric interfaces, similar to CNTs (see Background reference [32]), and thus will allow high mobility. From these considerations, it can be seen that GNRs have many of the strengths of nanotubes, minus many of their weaknesses.

In order to have useful devices, more than just metallic or semiconductor behavior is needed. Also needed is a way to gate the semiconductor ribbons in order to obtain switching and gain. The present invention gates graphene ribbons with metallic plates, or with another graphene ribbon orthogonal to the device. The lack of dangling bonds on the graphene surface enables high-k dielectric interfaces. Together with the long acoustic phonon-mean-free paths in graphene and their high thermal conductance (owing to the symmetry of their bands and their large C—C stiffness constants), this leads to ultra-high mobility of the gated graphene channel. While some of these properties exist for nanotubes, graphene devices are easier to scale in order to deliver a large drive current. This is in contrast with CNTs, which seem to suffer from fundamental alignment problems.

Additionally, GNRs can be used in graphene-ribbon circuits in which the devices are used by arranging them in a plane such that metallic and semiconductor alternate in order to create useful behavior. For example, two semiconductor GNRs in parallel can create an OR gate, and two GNRs in series can be used to create an AND gate.

Another important issue specific to GNRs (and not to CNTs) is the existence of dangling bonds at the ribbon edges. Depending on desired behavior, these edges can be kept active (see Background reference [32]) or passivated with other elements, such as H, carbon, silicon, germanium, grey tin, SiGe, SiC, AlAs, AlP, AlSb, BN, BP, GaAs, GaN, GaSb, InAs, InP, InSb, CdS, CdSe, CdTe, ZnO, ZnS, PbS, PbTe, or other oxides and materials known in the art used to chemically dope CNTs (see Background reference [11]). The way the edges are passivated can be an important feature of GNRs: By properly choosing elements (that could act like donors or acceptors) on the edges, it is possible to tune the electronic properties of the GNR, thus achieving more-interesting behaviors than those possible CNTs. An alternative to chemically doping the edges of GNRs is to electrostatically dope the GNR edges, a process that also has the benefit of being reversible.

Undoped GNR-based devices are intrinsically ambipolar; however, the desired NMOS- or PMOS-like asymmetric behavior can be obtained by shifting the Fermi level of the channel region by using metals with specific workfunctions for the gate or by doping chemically, electrostatically, or by other means.

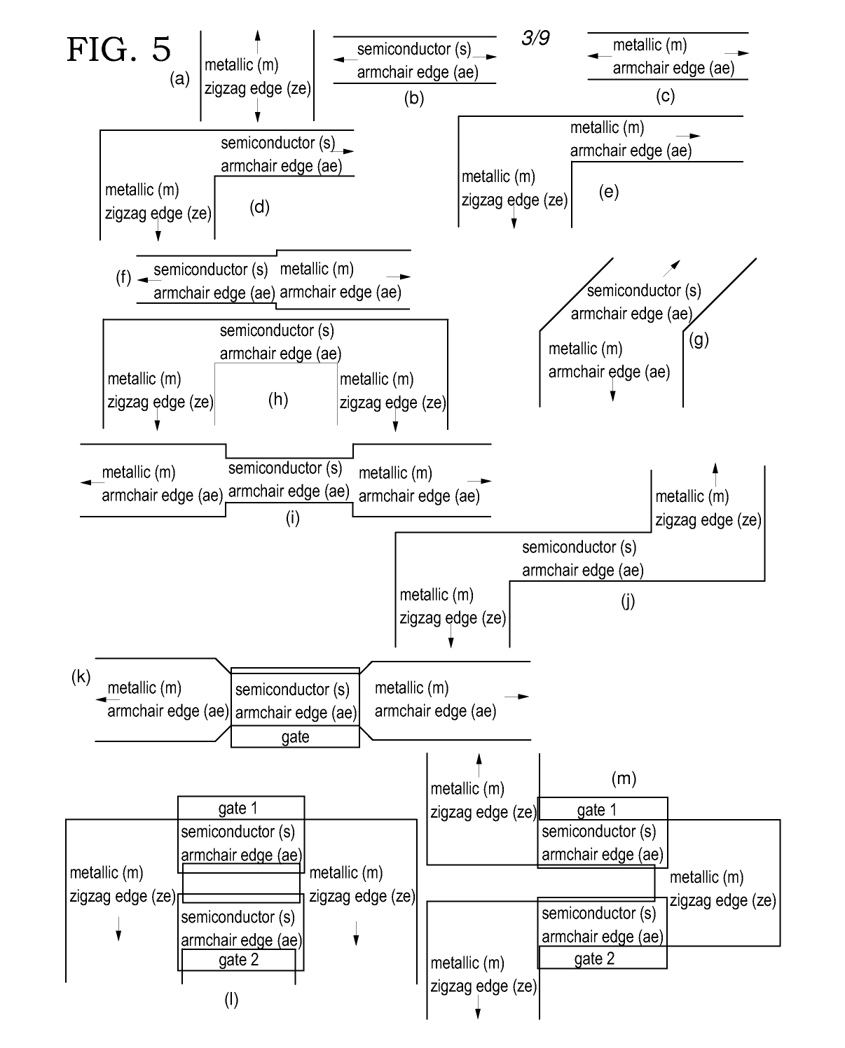

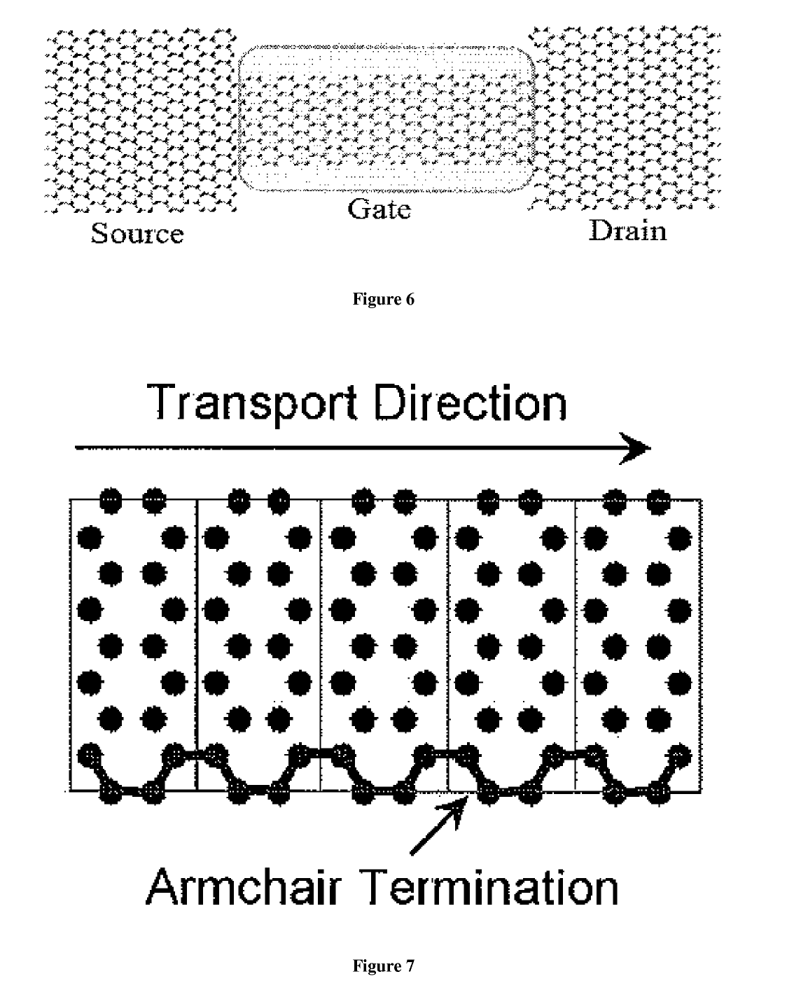

Some sample GNR structures that are proposed by the present invention are shown in FIG. 5, which shows simple one-dimensional ribbons, metallic or semiconductor, as well as simple two-ribbon junctions. Such simple structures are the building blocks for more-complicated multi-ribbon structures that can be gated in order to get active devices with gain for logic circuits, also shown in FIG. 5. For simplicity, FIG. 5 shows only the top-level pattern of the GNRs. For clarification, a more-detailed picture of one of the structures (FIG. 5(k), with the underlying honeycomb lattice, is shown in FIG. 6.

### Second Embodiment

### GNR-Based Transistor

This embodiment discloses a transistor based on graphene nanoribbons (GNRs), said switch having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a semiconducting GNR disposed on said substrate having a variable resistance electrically connected between said source GNR and said drain GNR, wherein said semiconducting GNR is disposed between said source GNR and said drain GNR, and wherein said semiconducting GNR edges are armchair-type; and a conductive gate GNR disposed on said substrate proximal and orthogonal to said semiconducting GNR, for controlling said resistance thereof, wherein said gate GNR is substantially metallic, wherein said gate GNR edges are zigzag-type, jagged-type, or armchair-type, wherein a first gap exists between said gate GNR and said source GNR, wherein a second gap exists between said gate GNR and said drain GNR, and wherein said semiconducting GNR spans said first and second gaps.

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

### Third Embodiment

### GNR NOT Gate

This embodiment discloses a NOT gate based on graphene nanoribbons (GNRs), said gate having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a semiconducting GNR disposed on said substrate electrically connected between said source GNR and said drain GNR, wherein said semiconducting GNR has two operational states, the first state being ON and the second state being OFF, wherein said semiconducting GNR has armchair edging, and wherein said semiconducting GNR is physically disposed in series at an angle of zero degrees relative to said source GNR and said drain GNR; and a conductive gate GNR disposed on said substrate proximal and orthogonal to said semiconducting GNR, for controlling said semiconducting GNR resistance thereof, wherein said gate GNR is substantially metallic, wherein said gate GNR edges are zigzag-type, jagged-type, or armchair-type, wherein a first gap exists between said gate GNR and said source GNR, wherein a second gap exists between said gate GNR and said drain GNR, wherein said semiconducting GNR spans said first and second gaps, and wherein when said semiconducting GNR turns OFF when a gate signal is applied, and turns ON when a gate signal is not applied.

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

### Fourth Embodiment

### GNR-Based Parallel-Transistor Network

This embodiment discloses a parallel-transistor network, said network based on graphene nanoribbons (GNRs), said network having at least two parallel GNR-based transistors, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said drain GNR, wherein said first semiconducting GNR has two operational states, the first state being ON and the second state being OFF, wherein said first semiconducting GNR has armchair edging, and wherein said first semiconducting GNR is physically disposed between said source GNR and said drain GNR; a second semiconducting GNR disposed on said substrate and electrically connected between the source and the drain, wherein said second semiconducting GNR has two operational states, the first state being ON and the second state being OFF, wherein said second semiconducting GNR has armchair edging, and wherein said second semiconducting GNR is physically disposed between said source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, wherein said first gate GNR edges are zigzag-type, jagged-type, or armchair-type, wherein a first gap exists between said first gate GNR and said source GNR, wherein a second gap exists between said first gate GNR and said drain GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, wherein said second gate GNR edges are zigzag-type, jagged-type, or armchair-type, wherein a third gap exists between said second gate GNR and said source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in parallel with each other

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

This embodiment can be further extended by adding one or more parallel transistors to the parallel-transistor network substrate in the same basic manner as was done for the first two parallel transistors described.

### Fifth Embodiment

### GNR-Based Series-Transistor Network

This embodiment discloses a series-transistor network, said network based on graphene nanoribbons (GNRs), said network having at least two GNR-based transistors in series with each other, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive intermediary drain/source GNR disposed on a substrate, wherein said intermediary drain/source GNR is substantially metallic, and wherein said intermediary drain/source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said intermediary drain/source GNR, wherein said first semiconducting GNR has two operational states, the first state being ON and the second state being OFF, wherein said first semiconducting GNR has armchair edging, and wherein said first semiconducting GNR is physically disposed between said source GNR and said intermediary drain/source GNR; a second semiconducting GNR disposed on said substrate and electrically connected between said intermediary drain/source GNR and said drain GNR, wherein said second semiconducting GNR has two operational states, the first state being ON and the second state being OFF, wherein said second semiconducting GNR has armchair edging, and wherein said second semiconducting GNR is physically disposed between said intermediary drain/source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, and wherein said first gate GNR edges are zigzag-type, jagged-type, or armchair-type, wherein a first gap exists between said first gate GNR and said source GNR, wherein a second gap exists between said first gate GNR and said intermediary drain/source GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, and wherein said second gate GNR edges are zigzag-type, jagged-type, or armchair-type, wherein a third gap exists between said second gate GNR and said intermediary drain/source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in series with each other.

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

This embodiment can be further extended by adding one or more series transistors to the parallel-transistor network substrate in the same basic manner as was done for the first two series transistors described. This will obviously require the use of additional intermediary drain/source GNRs in addition to the new transistors.

### Sixth Embodiment

### GNR Capacitor Device

This embodiment discloses a capacitor device based on graphene nanoribbons (GNRs), said capacitor having a substrate, said graphene originating from a continuous graphene sheet, said GNRs derived from said sheet using planar techniques, comprising: a first conductive surface GNR disposed on a substrate, wherein said first surface GNR is substantially metallic, wherein said first surface GNR edges are zigzag-type, jagged-type, or armchair-type, and wherein said first surface GNR is electrically connected to a first conductive GNR or graphene nanowire; a second conductive surface GNR disposed on a substrate, wherein said second surface GNR is substantially metallic, wherein said second surface GNR edges are zigzag-type, jagged-type, or armchair-type, and wherein said second surface GNR is electrically connected to a second conductive GNR or graphene nanowire; wherein said first and second surface GNRs are proximal with each other, but separated by a gap containing a dielectric material.

### Seventh Embodiment

### GNR-Based Integrated Circuit

This embodiment discloses an integrated circuit substantially based on graphene nanoribbons (GNRs), said integrated circuit comprising of any combination of transistors, NOT gates, OR gates, AND gates, and capacitors defined by the embodiments describing those devices above, respectively.

### Eighth Embodiment

### Method for Making a GNR-Based Transistor

This embodiment discloses a method for making a transistor based on graphene nanoribbons (GNRs), said switch having a substrate, said graphene originating from a continuous graphene sheet, said GNRs derived from said sheet using planar techniques, comprising the steps of: providing a conductive source GNR disposed on a substrate, wherein said source GNR is substantially metallic, and wherein said source GNR edges are zigzag-type, jagged-type, or armchair-type; providing a conductive drain GNR disposed on said substrate and spaced apart from the source, wherein said drain GNR is substantially metallic, and wherein said drain GNR edges are zigzag-type, jagged-type, or armchair-type; providing a semiconducting GNR disposed on said substrate having a variable resistance electrically connected between said source GNR and said drain GNR, wherein said semiconducting GNR is disposed between said source GNR and said drain GNR, and wherein said semiconducting GNR edges are armchair-type; and providing a conductive gate GNR disposed on said substrate proximal and orthogonal to said semiconducting GNR, for controlling said resistance thereof, wherein said gate GNR is substantially metallic, wherein said gate GNR edges are zigzag-type, jagged-type, or armchair-type, wherein a first gap exists between said gate GNR and said source GNR, wherein a second gap exists between said gate GNR and said drain GNR, and wherein said semiconducting GNR spans said first and second gaps.

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

### Ninth Embodiment

### Method for Making a GNR-Based Integrated Circuit

This embodiment discloses a method for making an integrated circuit substantially based on graphene nanoribbons (GNRs), said method comprising the steps of providing any combination of transistors, NOT gates, OR gates, AND gates, and capacitors defined by the embodiments describing those devices above, respectively.

### Tenth Embodiment

### A Computing System Using GNR-Based Devices

This embodiment discloses a computing system, said computing system having at least one microprocessor, said at least one microprocessor having transistors, NOT gates, OR gates, AND gates, and capacitors, wherein said computing system further comprises at least one transistor, NOT gate, OR gate, AND gate, or capacitor defined by the embodiments describing those devices above, respectively.

### Eleventh Embodiment

### A Computing Program Executed Using GNR-Based Devices

This embodiment discloses a computer program, said computing program executed by a computing system, said computing system having at least one microprocessor, said at least one microprocessor having transistors, NOT gates, OR gates, AND gates, and capacitors, wherein at least one transistor, NOT gate, OR gate, AND gate, or capacitor used in the execution of said computer program is defined by the embodiments describing those devices above, respectively.

### Twelfth Embodiment

### Method for Performing a GNR-Based NOT Calculation

This embodiment discloses a method for performing a NOT calculation using a NOT gate based on graphene nanoribbons (GNRs); said gate having a substrate, said graphene originating from a continuous graphene sheet; said GNRs derived from said sheet using planar techniques; said gate having a conductive source GNR disposed on a substrate, wherein said source GNR is substantially metallic, and wherein said source GNR edges are zigzag-type, jagged-type, or armchair-type; said gate having a conductive drain GNR disposed on said substrate and spaced apart from the source, wherein said drain GNR is substantially metallic, and wherein said drain GNR edges are zigzag-type, jagged-type, or armchair-type; said gate having a semiconducting GNR disposed on said substrate electrically connected between said source GNR and said drain GNR, wherein said semiconducting GNR has two operational states, the first state being ON and the second state being OFF, wherein said semiconducting GNR has armchair edging, and wherein said semiconducting GNR is physically disposed in series at an angle of zero degrees relative to said source GNR and said drain GNR; and said gate having a conductive gate GNR disposed on said substrate proximal and orthogonal to said semiconducting GNR, for controlling said semiconducting GNR resistance thereof, wherein said gate GNR is substantially metallic, wherein said gate GNR edges are zigzag-type, jagged-type, or armchair-type, wherein a first gap exists between said gate GNR and said source GNR, wherein a second gap exists between said gate GNR and said drain GNR, wherein said semiconducting GNR spans said first and second gaps, and wherein when said semiconducting GNR turns OFF when a gate signal is applied, and turns ON when a gate signal is not applied; said method comprising the steps of: making a power source available at said source GNR; applying a logical voltage signal to said gate GNR, wherein said logical signal is selected from the group consisting of “1” or “0”, wherein said logical voltage signal and its associated current path is configured to desaturate said semiconductor GNR if a logical “1” signal is applied, and wherein said logical voltage signal and its associated current path is configured to saturate said semiconductor GNR if a logical “0” signal is applied; and if said semiconductor GNR is saturated, then making said power source available to said drain GNR.

### Thirteenth Embodiment

### Method for Performing a GNR-Based OR Calculation

This embodiment discloses a method for performing an OR calculation using at least one parallel-transistor network, said network based on graphene nanoribbons (GNRs), said network having at least two parallel GNR-based transistors, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said drain GNR, wherein said first semiconducting GNR has two operational states, the first state being ON and the second state being OFF, wherein said first semiconducting GNR has armchair edging, and wherein said first semiconducting GNR is physically disposed between said source GNR and said drain GNR; a second semiconducting GNR disposed on said substrate and electrically connected between the source and the drain, wherein said second semiconducting GNR has two operational states, the first state being ON and the second state being OFF, wherein said second semiconducting GNR has armchair edging, and wherein said second semiconducting GNR is physically disposed between said source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, wherein said first gate GNR edges are zigzag-type, jagged-type, or armchair-type, wherein a first gap exists between said first gate GNR and said source GNR, wherein a second gap exists between said first gate GNR and said drain GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, wherein said second gate GNR edges are zigzag-type, jagged-type, or armchair-type, wherein a third gap exists between said second gate GNR and said source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in parallel with each other, said method comprising the steps of: making a power source available at said source GNR; applying a logical voltage signal to at least one of said first gate GNR or said second gate GNR, wherein said logical signal to said first gate GNR is selected from the group consisting of “1” or “0”, wherein said logical signal to said second gate GNR is selected from the group consisting of “1” or “0”, wherein said logical voltage signal to said first gate GNR and its associated current path is configured to saturate said first semiconductor GNR if a logical “1” signal is applied, wherein said logical voltage signal to said first gate GNR and its associated current path is configured to desaturate said first semiconductor GNR if a logical “0” signal is applied, wherein said logical voltage signal to said second gate GNR and its associated current path is configured to saturate said second semiconductor GNR if a logical “1” signal is applied, wherein said logical voltage signal to said second gate GNR and its associated current path is configured to desaturate said second semiconductor GNR if a logical “0” signal is applied; and if either said first semiconductor GNR is saturated or said second semiconductor GNR is saturated, then making said power source available to said drain GNR.

### Fourteenth Embodiment

### Method for Performing a GNR-Based AND Calculation

This embodiment discloses a method for performing an AND calculation using a at least one series-transistor network, said network based on graphene nanoribbons (GNRs), said network having at least two GNR-based transistors in series with each other, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive intermediary drain/source GNR disposed on a substrate, wherein said intermediary drain/source GNR is substantially metallic, and wherein said intermediary drain/source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said intermediary drain/source GNR, wherein said first semiconducting GNR has two operational states, the first state being ON and the second state being OFF, wherein said first semiconducting GNR has armchair edging, and wherein said first semiconducting GNR is physically disposed between said source GNR and said intermediary drain/source GNR; a second semiconducting GNR disposed on said substrate and electrically connected between said intermediary drain/source GNR and said drain GNR, wherein said second semiconducting GNR has two operational states, the first state being ON and the second state being OFF, wherein said second semiconducting GNR has armchair edging, and wherein said second semiconducting GNR is physically disposed between said intermediary drain/source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, and wherein said first gate GNR edges are zigzag-type, jagged-type, or armchair-type, wherein a first gap exists between said first gate GNR and said source GNR, wherein a second gap exists between said first gate GNR and said intermediary drain/source GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, and wherein said second gate GNR edges are zigzag-type, jagged-type, or armchair-type, wherein a third gap exists between said second gate GNR and said intermediary drain/source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in series with each other, said method comprising the steps of: making a power source available at said source GNR; applying a logical voltage signal to at least one of said first gate GNR or said second gate GNR, wherein said logical signal to said first gate GNR is selected from the group consisting of “1” or “0”, wherein said logical signal to said second gate GNR is selected from the group consisting of “1” or “0”, wherein said logical voltage signal to said first gate GNR and its associated current path is configured to saturate said first semiconductor GNR if a logical “1” signal is applied, wherein said logical voltage signal to said first gate GNR and its associated current path is configured to desaturate said first semiconductor GNR if a logical “0” signal is applied, wherein said logical voltage signal to said second gate GNR and its associated current path is configured to saturate said second semiconductor GNR if a logical “1” signal is applied, wherein said logical voltage signal to said second gate GNR and its associated current path is configured to desaturate said second semiconductor GNR if a logical “0” signal is applied; if said first semiconductor GNR is saturated, then making said power source available to said intermediary drain/source GNR; and if said second semiconductor GNR is saturated, then making any said power source that is available on said intermediary drain/source GNR available to said drain GNR.

### Fifteenth Embodiment

### Method for Making a GNR-Based Parallel-Transistor Network

This embodiment discloses a method for making a parallel-transistor network, said network based on graphene nanoribbons (GNRs), said network having at least two parallel GNR-based transistors, said network having a substrate, said graphene originating from a continuous graphene sheet, said GNRs derived from said sheet using planar techniques, said method comprising the steps of: providing a conductive source GNR disposed on a substrate, wherein said source GNR is substantially metallic, and wherein said source GNR edges are zigzag-type, jagged-type, or armchair-type; providing a conductive drain GNR disposed on said substrate and spaced apart from the source, wherein said drain GNR is substantially metallic, and wherein said drain GNR edges are zigzag-type, jagged-type, or armchair-type; providing a first semiconducting GNR disposed on said substrate and electrically connected between said source GNR and said drain GNR, wherein said first semiconducting GNR has two operational states, the first state being ON and the second state being OFF, wherein said first semiconducting GNR has armchair edging, and wherein said first semiconducting GNR is physically disposed between said source GNR and said drain GNR; providing a second semiconducting GNR disposed on said substrate and electrically connected between the source and the drain, wherein said second semiconducting GNR has two operational states, the first state being ON and the second state being OFF, wherein said second semiconducting GNR has armchair edging, and wherein said second semiconducting GNR is physically disposed between said source GNR and said drain GNR; providing a first conductive gate GNR disposed on said substrate proximal and orthogonal to said first semiconducting GNR, for controlling said first semiconducting GNR resistance thereof, wherein said first gate GNR is substantially metallic, wherein said first gate GNR edges are zigzag-type, jagged-type, or armchair-type, wherein a first gap exists between said first gate GNR and said source GNR, wherein a second gap exists between said first gate GNR and said drain GNR, wherein said first semiconducting GNR spans said first and second gaps, and wherein when said first gate GNR changes the conducting state of said first semiconducting GNR between ON and OFF based on an applied signal by way of said first gate GNR; providing a second conductive gate GNR disposed on said substrate proximal and orthogonal to said second semiconducting GNR, for controlling said second semiconducting GNR resistance thereof, wherein said second gate GNR is substantially metallic, wherein said second gate GNR edges are zigzag-type, jagged-type, or armchair-type, wherein a third gap exists between said second gate GNR and said source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in parallel with each other

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

This embodiment can be further extended by adding one or more parallel transistors to the parallel-transistor network substrate in the same basic manner as was done for the first two parallel transistors described.

### Sixteenth Embodiment

### Method for Making a GNR-Based Series-Transistor Network

This embodiment discloses a method for making a series-transistor network, said network based on graphene nanoribbons (GNRs), said network having at least two GNR-based transistors in series with each other, said network having a substrate, said graphene originating from a continuous graphene sheet, said GNRs derived from said sheet using planar techniques, said method comprising the steps of: providing a conductive source GNR disposed on a substrate, wherein said source GNR is substantially metallic, and wherein said source GNR edges are zigzag-type, jagged-type, or armchair-type; a conductive intermediary drain/source GNR disposed on a substrate, wherein said intermediary drain/source GNR is substantially metallic, and wherein said intermediary drain/source GNR edges are zigzag-type, jagged-type, or armchair-type; providing a conductive drain GNR disposed on said substrate and spaced apart from the source, wherein said drain GNR is substantially metallic, and wherein said drain GNR edges are zigzag-type, jagged-type, or armchair-type; providing a first semiconducting GNR disposed on said substrate and electrically connected between said source GNR and said intermediary drain/source GNR, wherein said first semiconducting GNR has two operational states, the first state being ON and the second state being OFF, wherein said first semiconducting GNR has armchair edging, and wherein said first semiconducting GNR is physically disposed between said source GNR and said intermediary drain/source GNR; providing a second semiconducting GNR disposed on said substrate and electrically connected between said intermediary drain/source GNR and said drain GNR, wherein said second semiconducting GNR has two operational states, the first state being ON and the second state being OFF, wherein said second semiconducting GNR has armchair edging, and wherein said second semiconducting GNR is physically disposed between said intermediary drain/source GNR and said drain GNR; providing a first conductive gate GNR disposed on said substrate proximal and orthogonal to said first semiconducting GNR, for controlling said first semiconducting GNR resistance thereof, wherein said first gate GNR is substantially metallic, and wherein said first gate GNR edges are zigzag-type, jagged-type, or armchair-type, wherein a first gap exists between said first gate GNR and said source GNR, wherein a second gap exists between said first gate GNR and said intermediary drain/source GNR, wherein said first semiconducting GNR spans said first and second gaps, and wherein when said first gate GNR changes the conducting state of said first semiconducting GNR between ON and OFF based on an applied signal by way of said first gate GNR; providing a second conductive gate GNR disposed on said substrate proximal and orthogonal to said second semiconducting GNR, for controlling said second semiconducting GNR resistance thereof, wherein said second gate GNR is substantially metallic, and wherein said second gate GNR edges are zigzag-type, jagged-type, or armchair-type, wherein a third gap exists between said second gate GNR and said intermediary drain/source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in series with each other.

This embodiment can be further extended wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

This embodiment can be further extended wherein said semiconducting GNR is passivated with a semiconducting material that is n-type or is p-type.

This embodiment can be further extended wherein the edges of said semiconducting GNR are doped to form a doping profile, wherein said doping profile is selected from the group consisting of NPN, PNP, PIP, NIN, and PIN.

This embodiment can be further extended wherein said doping is accomplished by chemical-doping means or by electrostatic-doping.

This embodiment can be further extended by adding one or more series transistors to the parallel-transistor network substrate in the same basic manner as was done for the first two series transistors described. This will obviously require the use of additional intermediary drain/source GNRs in addition to the new transistors.

### Seventeenth Embodiment

### Method for Making a GNR-Based Capacitor Device

This embodiment discloses a method for making a capacitor device based on graphene nanoribbons (GNRs), said capacitor having a substrate, said graphene originating from a continuous graphene sheet, said GNRs derived from said sheet using planar techniques, said method comprising the steps of: providing a first conductive surface GNR disposed on a substrate, wherein said first surface GNR is substantially metallic, wherein said first surface GNR edges are zigzag-type, jagged-type, or armchair-type, and wherein said first surface GNR is electrically connected to a first conductive GNR or graphene nanowire; providing a second conductive surface GNR disposed on a substrate, wherein said second surface GNR is substantially metallic, wherein said second surface GNR edges are zigzag-type, jagged-type, or armchair-type, and wherein said second surface GNR is electrically connected to a second conductive GNR or graphene nanowire; wherein said first and second surface GNRs are proximal with each other, but separated by a gap containing a dielectric material.

### Obvious Variations

Overall, the various embodiments of the present invention generally provides monolithically integrated graphene nanoribbon (GNR) devices, interconnect, and circuits that overcome most of the difficulties with carbon nano-tube (CNT) devices and circuits, by having implicit control over the chirality, being self-aligned, and having no interface mismatch between the device and interconnect regions.

The various embodiments of the present invention may be utilized and/or combined for a number of products and services, such as, but not limited to, devices and circuits that could potentially revolutionize the semiconductor industry. Many groups of researchers are pursuing ideas that could either allow further scaling (“More Moore”), or find a worthy alternative to CMOS (“Beyond Moore”). GNRs, like CNTs, fall mostly in the “More Moore” category, but with extremely attractive characteristics. The various embodiments of the present invention offers, among other things, an alternative to CNTs by providing distinct advantages over CNTs, as GNRs do not require difficult arrangement of the devices, can offer superior chirality control, and have perfect interfaces between devices and interconnects, with no defects. Moreover, as compared to CMOS, the graphene structures described herein scale to very small dimensions, and offer superior electronic properties (faster operation at lower power consumption).

Notwithstanding, those skilled in the art will have no difficulty devising myriad obvious variations and improvements to the present invention, all of which are intended to be encompassed within the scope of the claims which follow.

What is claimed is:

1. A transistor based on graphene nanoribbons (GNRs), said switch having a substrate, said graphene originating from a continuous graphene sheet, said GNRs derived from said sheet using planar techniques, comprising:
a conductive source GNR disposed on a substrate,
wherein said source GNR is substantially metallic, and
wherein said source GNR edges are zigzag-type, jagged-type, or armchair-type;
a conductive drain GNR disposed on said substrate and spaced apart from the source,
wherein said drain GNR is substantially metallic, and
wherein said drain GNR edges are zigzag-type, jagged-type, or armchair-type;
a semiconducting GNR disposed on said substrate having a variable resistance electrically connected between said source GNR and said drain GNR,
wherein said semiconducting GNR is disposed between said source GNR and said drain GNR, and
wherein said semiconducting GNR edges are armchair-type; and
a conductive gate GNR disposed on said substrate proximal and orthogonal to said semiconducting GNR, for controlling said resistance thereof,
wherein said gate GNR is substantially metallic,
wherein said gate GNR edges are zigzag-type, jagged-type, or armchair-type,
wherein a first gap exists between said gate GNR and said source GNR,
wherein a second gap exists between said gate GNR and said drain GNR, and
wherein said semiconducting GNR spans said first and second gaps.

2. The transistor of claim 1, wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

3. The transistor of claim 1, wherein said semiconducting GNR is passivated with a semiconducting material that is n-type or is p-type.

4. The transistor of claim 1, wherein the edges of said semiconducting GNR are doped to form a doping profile, wherein said doping profile is selected from the group consisting of NPN, PNP, PIP, NIN, and PIN.

5. The transistor of claim 4, wherein said doping is accomplished by chemical-doping means.

6. The transistor of claim 4, wherein said doping is accomplished by electrostatic-doping.

7. A NOT gate based on graphene nanoribbons (GNRs), said gate having a substrate, said graphene originating from a continuous graphene sheet, said GNRs derived from said sheet using planar techniques, comprising:
a conductive source GNR disposed on a substrate,
wherein said source GNR is substantially metallic, and
wherein said source GNR edges are zigzag-type, jagged-type, or armchair-type;
a conductive drain GNR disposed on said substrate and spaced apart from the source,
wherein said drain GNR is substantially metallic, and
wherein said drain GNR edges are zigzag-type, jagged-type, or armchair-type;
a semiconducting GNR disposed on said substrate and electrically connected between said source GNR and said drain GNR,
wherein said semiconducting GNR has two operational states, the first state being ON and the second state being OFF,
wherein said semiconducting GNR has armchair edging, and
wherein said semiconducting GNR is physically disposed in series at an angle of zero degrees relative to said source GNR and said drain GNR; and
a conductive gate GNR disposed on said substrate proximal and orthogonal to said semiconducting GNR, for controlling said semiconducting GNR resistance thereof,
wherein said gate GNR is substantially metallic,
wherein said gate GNR edges are zigzag-type, jagged-type, or armchair-type,
wherein a first gap exists between said gate GNR and said source GNR,
wherein a second gap exists between said gate GNR and said drain GNR,
wherein said semiconducting GNR spans said first and second gaps, and
wherein when said semiconducting GNR turns OFF when a gate signal is applied, and turns ON when a gate signal is not applied.

8. The NOT gate of claim 7, wherein said semiconducting GNR is passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

9. The NOT gate of claim 7, wherein said semiconducting GNR is passivated with a semiconducting material that is n-type or is p-type.

10. The NOT gate of claim 7, wherein the edges of said semiconducting GNR are doped to form a doping profile, wherein said doping profile is selected from the group consisting of NPN, PNP, PIP, NIN, and PIN.

11. The NOT gate of claim 10, wherein said doping is accomplished by chemical-doping means.

12. The NOT gate of claim 10, wherein said doping is accomplished by electrostatic-doping.

13. A parallel-transistor network, said network based on graphene nanoribbons (GNRs), said network having at least two parallel GNR-based transistors, said network having a substrate, said graphene originating from a continuous graphene sheet, said GNRs derived from said sheet using planar techniques, comprising:
a conductive source GNR disposed on a substrate,
wherein said source GNR is substantially metallic, and
wherein said source GNR edges are zigzag-type, jagged-type, or armchair-type;
a conductive drain GNR disposed on said substrate and spaced apart from the source,
wherein said drain GNR is substantially metallic, and
wherein said drain GNR edges are zigzag-type, jagged-type, or armchair-type;
a first semiconducting GNR disposed on said substrate and electrically connected between said source GNR and said drain GNR,
wherein said first semiconducting GNR has two operational states, the first state being ON and the second state being OFF,
wherein said first semiconducting GNR has armchair edging, and
wherein said first semiconducting GNR is physically disposed between said source GNR and said drain GNR;
a second semiconducting GNR disposed on said substrate and electrically connected between the source and the drain,
wherein said second semiconducting GNR has two operational states, the first state being ON and the second state being OFF,
wherein said second semiconducting GNR has armchair edging, and
wherein said second semiconducting GNR is physically disposed between said source GNR and said drain GNR;
a first conductive gate GNR disposed on said substrate proximal and orthogonal to said first semiconducting GNR, for controlling said first semiconducting GNR resistance thereof,
wherein said first gate GNR is substantially metallic,
wherein said first gate GNR edges are zigzag-type, jagged-type, or armchair-type,
wherein a first gap exists between said first gate GNR and said source GNR,
wherein a second gap exists between said first gate GNR and said drain GNR,
wherein said first semiconducting GNR spans said first and second gaps, and
wherein when said first gate GNR changes the conducting state of said first semiconducting GNR between ON and OFF based on an applied signal by way of said first gate GNR;
a second conductive gate GNR disposed on said substrate proximal and orthogonal to said second semiconducting GNR, for controlling said second semiconducting GNR resistance thereof,
wherein said second gate GNR is substantially metallic,
wherein said second gate GNR edges are zigzag-type, jagged-type, or armchair-type,
wherein a third gap exists between said second gate GNR and said source GNR,
wherein a fourth gap exists between said second gate GNR and said drain GNR,
wherein said second semiconducting GNR spans said third and fourth gaps, and
wherein when said second gate GNR changes the conducting state of said second semiconducting GNR between ON and OFF based on an applied signal by way of said second gate GNR;
wherein the power-output-current paths for said first and second semiconducting GNRs are electrically connected in parallel with each other.

14. The parallel-transistor network of claim 13, wherein said first and second semiconducting GNRs are each passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

15. The parallel-transistor network of claim 13, wherein said first and second semiconducting GNRs are each passivated with a semiconducting material that is n-type or is p-type.

16. The parallel-transistor network of claim 13, wherein the edges for each of said first and second semiconducting GNRs are doped to form a doping profile, wherein said doping profile is selected from the group consisting of NPN, PNP, PIP, NIN, and PIN.

17. The parallel-transistor network of claim 16, wherein said doping is accomplished by chemical-doping means.

18. The parallel-transistor network of claim 16, wherein said doping is accomplished by electrostatic-doping.

19. The parallel-transistor network of claim 13, further comprising a third parallel GNR-based transistor on said substrate, said third parallel GNR-based transistor comprising:
a third semiconducting GNR disposed on said substrate and electrically connected between said source GNR and said drain GNR,
wherein said third semiconducting GNR has two operational states, the first state being ON and the second state being OFF,
wherein said third semiconducting GNR has armchair edging, and
wherein said third semiconducting GNR is physically disposed between said source GNR and said drain GNR; and
a third conductive gate GNR disposed on said substrate proximal and orthogonal to said third semiconducting GNR, for controlling said third semiconducting GNR resistance thereof,
wherein said third gate GNR is substantially metallic,
wherein said third gate GNR edges are zigzag-type, jagged-type, or armchair-type,
wherein a fifth gap exists between said third gate GNR and said source GNR,
wherein a sixth gap exists between said third gate GNR and said drain GNR,
wherein said third semiconducting GNR spans said fifth and sixth gaps, and
wherein when said third gate GNR changes the conducting state of said third semiconducting GNR between ON and OFF based on an applied signal by way of said third gate GNR;
wherein the power-output-current paths for said first, second, and third semiconducting GNRs are electrically connected in parallel with each other.

20. The parallel-transistor network of claim 19, further comprising a fourth parallel GNR-based transistor on said substrate, said fourth parallel GNR-based transistor comprising:
a fourth semiconducting GNR disposed on said substrate and electrically connected between said source GNR and said drain GNR,
wherein said fourth semiconducting GNR has two operational states, the first state being ON and the second state being OFF,
wherein said fourth semiconducting GNR has armchair edging, and
wherein said fourth semiconducting GNR is physically disposed between said source GNR and said drain GNR; and
a fourth conductive gate GNR disposed on said substrate proximal and orthogonal to said fourth semiconducting GNR, for controlling said fourth semiconducting GNR resistance thereof,
wherein said fourth gate GNR is substantially metallic,
wherein said fourth gate GNR edges are zigzag-type, jagged-type, or armchair-type,
wherein a seventh gap exists between said fourth gate GNR and said source GNR,
wherein an eighth gap exists between said fourth gate GNR and said drain GNR,
wherein said fourth semiconducting GNR spans said seventh and eighth gaps, and
wherein when said fourth gate GNR changes the conducting state of said fourth semiconducting GNR between ON and OFF based on an applied signal by way of said fourth gate GNR;
wherein the power-output-current paths for said first, second, third, and fourth semiconducting GNRs are electrically connected in parallel with each other.

21. A series-transistor network, said network based on graphene nanoribbons (GNRs), said network having at least two GNR-based transistors in series with each other, said network having a substrate, said graphene originating from a continuous graphene sheet, said GNRs derived from said sheet using planar techniques, comprising:
a conductive source GNR disposed on a substrate,
wherein said source GNR is substantially metallic, and
wherein said source GNR edges are zigzag-type, jagged-type, or armchair-type;
a conductive intermediary drain/source GNR disposed on a substrate,
wherein said intermediary drain/source GNR is substantially metallic, and
wherein said intermediary drain/source GNR edges are zigzag-type, jagged-type, or armchair-type;
a conductive drain GNR disposed on said substrate and spaced apart from the source,
wherein said drain GNR is substantially metallic, and
wherein said drain GNR edges are zigzag-type, jagged-type, or armchair-type;
a first semiconducting GNR disposed on said substrate and electrically connected between said source GNR and said intermediary drain/source GNR,
wherein said first semiconducting GNR has two operational states, the first state being ON and the second state being OFF,
wherein said first semiconducting GNR has armchair edging, and
wherein said first semiconducting GNR is physically disposed between said source GNR and said intermediary drain/source GNR;
a second semiconducting GNR disposed on said substrate and electrically connected between said intermediary drain/source GNR and said drain GNR,
wherein said second semiconducting GNR has two operational states, the first state being ON and the second state being OFF,
wherein said second semiconducting GNR has armchair edging, and
wherein said second semiconducting GNR is physically disposed between said intermediary drain/source GNR and said drain GNR;
a first conductive gate GNR disposed on said substrate proximal and orthogonal to said first semiconducting GNR, for controlling said first semiconducting GNR resistance thereof,
wherein said first gate GNR is substantially metallic, and
wherein said first gate GNR edges are zigzag-type, jagged-type, or armchair-type,
wherein a first gap exists between said first gate GNR and said source GNR,
wherein a second gap exists between said first gate GNR and said intermediary drain/source GNR,
wherein said first semiconducting GNR spans said first and second gaps, and
wherein when said first gate GNR changes the conducting state of said first semiconducting GNR between ON and OFF based on an applied signal by way of said first gate GNR;
a second conductive gate GNR disposed on said substrate proximal and orthogonal to said second semiconducting GNR, for controlling said second semiconducting GNR resistance thereof,
wherein said second gate GNR is substantially metallic, and
wherein said second gate GNR edges are zigzag-type, jagged-type, or armchair-type,
wherein a third gap exists between said second gate GNR and said intermediary drain/source GNR,
wherein a fourth gap exists between said second gate GNR and said drain GNR,
wherein said second semiconducting GNR spans said third and fourth gaps, and
wherein when said second gate GNR changes the conducting state of said second semiconducting GNR between ON and OFF based on an applied signal by way of said second gate GNR;
wherein the power-output-current paths for said first and second semiconducting GNRs are electrically connected in series with each other.

22. The series-transistor network of claim 21, wherein said first and second semiconducting GNRs are each passivated with an element selected from the group consisting of carbon, silicon, germanium, grey tin, SiGe, SiC, AlAs, AlP, AlSb, BN, BP, GaAs, GaN, GaSb, H, InAs, InP, InSb, CdS, CdSe, CdTe, ZnO, ZnS, PbS, and PbTe.

23. The series-transistor network of claim 21, wherein said first and second semiconducting GNRs are each passivated with a semiconducting material that is n-type or is p-type.

24. The series-transistor network of claim 21, wherein the edges for each of said first and second semiconducting GNRs are doped to form a doping profile, wherein said doping profile is selected from the group consisting of NPN, PNP, PIP, NIN, and PIN.

25. The series-transistor network of claim 24, wherein said doping is accomplished by chemical-doping means.

26. The series-transistor network of claim 24, wherein said doping is accomplished by electrostatic-doping.

27. The series-transistor network of claim 21, further comprising a third series GNR-based transistor on said substrate, said third series GNR-based transistor comprising:
a supplemental drain GNR disposed on a substrate,
wherein said supplemental drain GNR is substantially metallic, and
wherein said supplemental drain GNR edges are zigzag-type, jagged-type, or armchair-type;
a third semiconducting GNR disposed on said substrate and electrically connected between said drain GNR, which acts as a source for said third semiconducting GNR, and said supplemental drain GNR,
wherein said third semiconducting GNR has two operational states, the first state being ON and the second state being OFF,
wherein said third semiconducting GNR has armchair edging, and
wherein said third semiconducting GNR is physically disposed between said drain GNR and said supplemental drain GNR; and
a third conductive gate GNR disposed on said substrate proximal and orthogonal to said third semiconducting GNR, for controlling said third semiconducting GNR resistance thereof,
wherein said third gate GNR is substantially metallic,
wherein said third gate GNR edges are zigzag-type, jagged-type, or armchair-type,
wherein a fifth gap exists between said third gate GNR and said drain GNR,
wherein a sixth gap exists between said third gate GNR and said supplemental drain GNR,
wherein said third semiconducting GNR spans said fifth and sixth gaps, and
wherein when said third gate GNR changes the conducting state of said third semiconducting GNR between ON and OFF based on an applied signal by way of said third gate GNR;
wherein the power-output-current paths for said first, second, and third semiconducting GNRs are electrically connected in series with each other.

28. The series-transistor network of claim 27, further comprising a fourth series GNR-based transistor on said substrate, said fourth series GNR-based transistor comprising:
a second supplemental drain GNR disposed on a substrate,
wherein said second supplemental drain GNR is substantially metallic, and
wherein said supplemental drain GNR edges are zigzag-type, jagged-type, or armchair-type;
a fourth semiconducting GNR disposed on said substrate and electrically connected between said supplemental drain GNR, which acts as a source for said fourth semiconducting GNR, and said second supplemental drain GNR,
wherein said fourth semiconducting GNR has two operational states, the first state being ON and the second state being OFF,
wherein said fourth semiconducting GNR has armchair edging, and
wherein said fourth semiconducting GNR is physically disposed between said supplemental drain GNR and said second supplemental drain GNR; and
a fourth conductive gate GNR disposed on said substrate proximal and orthogonal to said fourth semiconducting GNR, for controlling said fourth semiconducting GNR resistance thereof,
wherein said fourth gate GNR is substantially metallic,
wherein said fourth gate GNR edges are zigzag-type, jagged-type, or armchair-type,
wherein a seventh gap exists between said fourth gate GNR and said supplemental drain GNR,
wherein an eighth gap exists between said fourth gate GNR and said second supplemental drain GNR,
wherein said fourth semiconducting GNR spans said seventh and eighth gaps, and
wherein when said fourth gate GNR changes the conducting state of said fourth semiconducting GNR between ON and OFF based on an applied signal by way of said fourth gate GNR;
wherein the power-output-current paths for said first, second, third, and fourth semiconducting GNRs are electrically connected in series with each other.

29. A capacitor device based on graphene nanoribbons (GNRs), said capacitor having a substrate, said graphene originating from a continuous graphene sheet, said GNRs derived from said sheet using planar techniques, comprising:
a first conductive surface GNR disposed on a substrate,
wherein said first surface GNR is substantially metallic,
wherein said first surface GNR edges are zigzag-type, jagged-type, or armchair-type, and
wherein said first surface GNR is electrically connected to a first conductive GNR or graphene nanowire;
a second conductive surface GNR disposed on a substrate,
wherein said second surface GNR is substantially metallic,
wherein said second surface GNR edges are zigzag-type, jagged-type, or armchair-type, and
wherein said second surface GNR is electrically connected to a second conductive GNR or graphene nanowire;
wherein said first and second surface GNRs are proximal with each other, but separated by a gap containing a dielectric material.

30. An integrated circuit substantially based on graphene nanoribbons (GNRs), said integrated circuit comprising of any combination of transistors, NOT gates, parallel-transistor network, series-transistor networks, and capacitors defined by claims 1, 7, 13, 21, and 29, respectively.

31. A method for performing a NOT calculation using a NOT gate based on graphene nanoribbons (GNRs); said gate having a substrate, said graphene originating from a continuous graphene sheet; said GNRs derived from said sheet using planar techniques; said gate having a conductive source GNR disposed on a substrate, wherein said source GNR is substantially metallic, and wherein said source GNR edges are zigzag-type, jagged-type, or armchair-type; said gate having a conductive drain GNR disposed on said substrate and spaced apart from the source, wherein said drain GNR is substantially metallic, and wherein said drain GNR edges are zigzag-type, jagged-type, or armchair-type; said gate having a semiconducting GNR disposed on said substrate electrically connected between said source GNR and said drain GNR, wherein said semiconducting GNR has two operational states, the first state being ON and the second state being OFF, wherein said semiconducting GNR has armchair edging, and wherein said semiconducting GNR is physically disposed in series at an angle of zero degrees relative to said source GNR and said drain GNR; and said gate having a conductive gate GNR disposed on said substrate proximal and orthogonal to said semiconducting GNR, for controlling said semiconducting GNR resistance thereof, wherein said gate GNR is substantially metallic, wherein said gate GNR edges are zigzag-type, jagged-type, or armchair-type, wherein a first gap exists between said gate GNR and said source GNR, wherein a second gap exists between said gate GNR and said drain GNR, wherein said semiconducting GNR spans said first and second gaps, and wherein when said semiconducting GNR turns OFF when a gate signal is applied, and turns ON when a gate signal is not applied; said method comprising the steps of:
making a power source available at said source GNR;
applying a logical voltage signal to said gate GNR,
wherein said logical signal is selected from the group consisting of “1” or “0”,
wherein said logical voltage signal and its associated current path is configured to desaturate said semiconductor GNR if a logical “1” signal is applied, and
wherein said logical voltage signal and its associated current path is configured to saturate said semiconductor GNR if a logical “0” signal is applied; and
if said semiconductor GNR is saturated, then making said power source available to said drain GNR.

32. A method for performing an OR calculation using at least one parallel-transistor network, said network based on graphene nanoribbons (GNRs), said network having at least two parallel GNR-based transistors, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said drain GNR, wherein said first semiconducting GNR has two operational states, the first state being ON and the second state being OFF, wherein said first semiconducting GNR has armchair edging, and wherein said first semiconducting GNR is physically disposed between said source GNR and said drain GNR; a second semiconducting GNR disposed on said substrate and electrically connected between the source and the drain, wherein said second semiconducting GNR has two operational states, the first state being ON and the second state being OFF, wherein said second semiconducting GNR has armchair edging, and wherein said second semiconducting GNR is physically disposed between said source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, wherein said first gate GNR edges are zigzag-type, jagged-type, or armchair-type, wherein a first gap exists between said first gate GNR and said source GNR, wherein a second gap exists between said first gate GNR and said drain GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, wherein said second gate GNR edges are zigzag-type, jagged-type, or armchair-type, wherein a third gap exists between said second gate GNR and said source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in parallel with each other, said method comprising the steps of:
making a power source available at said source GNR;
applying a logical voltage signal to at least one of said first gate GNR or said second gate GNR,
wherein said logical signal to said first gate GNR is selected from the group consisting of “1” or “0”,
wherein said logical signal to said second gate GNR is selected from the group consisting of “1” or “0”,
wherein said logical voltage signal to said first gate GNR and its associated current path is configured to saturate said first semiconductor GNR if a logical “1” signal is applied,
wherein said logical voltage signal to said first gate GNR and its associated current path is configured to desaturate said first semiconductor GNR if a logical “0” signal is applied,
wherein said logical voltage signal to said second gate GNR and its associated current path is configured to saturate said second semiconductor GNR if a logical “1” signal is applied,
wherein said logical voltage signal to said second gate GNR and its associated current path is configured to desaturate said second semiconductor GNR if a logical “0” signal is applied; and
if either said first semiconductor GNR is saturated or said second semiconductor GNR is saturated, then making said power source available to said drain GNR.

33. A method for performing an AND calculation using a at least one series-transistor network, said network based on graphene nanoribbons (GNRs), said network having at least two GNR-based transistors in series with each other, said network having a substrate, said graphene originating from a continuous graphene sheet, said GNRs derived from said sheet using planar techniques, comprising: a conductive source GNR disposed on a substrate, wherein said source GNR is substantially metallic, and wherein said source GNR edges are zigzag-type, jagged-type, or armchair-type; a conductive intermediary drain/source GNR disposed on a substrate, wherein said intermediary drain/source GNR is substantially metallic, and wherein said intermediary drain/source GNR edges are zigzag-type, jagged-type, or armchair-type; a conductive drain GNR disposed on said substrate and spaced apart from the source, wherein said drain GNR is substantially metallic, and wherein said drain GNR edges are zigzag-type, jagged-type, or armchair-type; a first semiconducting GNR disposed on said substrate and electrically connected between said source GNR and said intermediary drain/source GNR, wherein said first semiconducting GNR has two operational states, the first state being ON and the second state being OFF, wherein said first semiconducting GNR has armchair edging, and wherein said first semiconducting GNR is physically disposed between said source GNR and said intermediary drain/source GNR; a second semiconducting GNR disposed on said substrate and electrically connected between said intermediary drain/source GNR and said drain GNR, wherein said second semiconducting GNR has two operational states, the first state being ON and the second state being OFF, wherein said second semiconducting GNR has armchair edging, and wherein said second semiconducting GNR is physically disposed between said intermediary drain/source GNR and said drain GNR; a first conductive gate GNR disposed on said substrate proximal and orthogonal to said first semiconducting GNR, for controlling said first semiconducting GNR resistance thereof, wherein said first gate GNR is substantially metallic, and wherein said first gate GNR edges are zigzag-type, jagged-type, or armchair-type, wherein a first gap exists between said first gate GNR and said source GNR, wherein a second gap exists between said first gate GNR and said intermediary drain/source GNR, wherein said first semiconducting GNR spans said first and second gaps, and wherein when said first gate GNR changes the conducting state of said first semiconducting GNR between ON and OFF based on an applied signal by way of said first gate GNR; a second conductive gate GNR disposed on said substrate proximal and orthogonal to said second semiconducting GNR, for controlling said second semiconducting GNR resistance thereof, wherein said second gate GNR is substantially metallic, and wherein said second gate GNR edges are zigzag-type, jagged-type, or armchair-type, wherein a third gap exists between said second gate GNR and said intermediary drain/source GNR, wherein a fourth gap exists between said second gate GNR and said drain GNR, wherein said second semiconducting GNR spans said third and fourth gaps, and wherein when said second gate GNR changes the conducting state of said second semiconducting GNR between ON and OFF based on an applied signal by way of said second gate GNR; wherein the power-output-current paths for said first and second semiconducting GNRs are electrically connected in series with each other, said method comprising the steps of:
making a power source available at said source GNR;
applying a logical voltage signal to at least one of said first gate GNR or said second gate GNR,
wherein said logical signal to said first gate GNR is selected from the group consisting of “1” or “0”,
wherein said logical signal to said second gate GNR is selected from the group consisting of “1” or “0”,
wherein said logical voltage signal to said first gate GNR and its associated current path is configured to saturate said first semiconductor GNR if a logical “1” signal is applied,
wherein said logical voltage signal to said first gate GNR and its associated current path is configured to desaturate said first semiconductor GNR if a logical “0” signal is applied,
wherein said logical voltage signal to said second gate GNR and its associated current path is configured to saturate said second semiconductor GNR if a logical “1” signal is applied,
wherein said logical voltage signal to said second gate GNR and its associated current path is configured to desaturate said second semiconductor GNR if a logical “0” signal is applied;
if said first semiconductor GNR is saturated, then making said power source available to said intermediary drain/source GNR; and
if said second semiconductor GNR is saturated, then making any said power source that is available on said intermediary drain/source GNR available to said drain GNR.
